(19) United States
(12) Patent Application Publication
(10) Pub. No.: US 2025/0353193 A1
(43) Pub. Date: Nov. 20, 2025

(54) WAFER-HANDLING END EFFECTORS CONFIGURED TO SELECTIVELY ENGAGE A WAFER VIA A PRESSURE FORCE AND TO SELECTIVELY GRIP THE WAFER VIA A VACUUM FORCE, WAFER-HANDLING UNITS THAT INCLUDE THE WAFER-HANDLING END EFFECTORS, SYSTEMS THAT INCLUDE THE WAFER-HANDLING UNITS, AND METHODS OF UTILIZING WAFER-HANDLING END EFFECTORS

(71) Applicant: FormFactor, Inc., Livermore, CA (US)

(72) Inventors: Samuel Grasemann, Thiendorf (DE); Benedikt Marx, Dresden (DE)

(21) Appl. No.: 19/057,462

(22) Filed: Feb. 19, 2025

Related U.S. Application Data
(60) Provisional application No. 63/648,060, filed on May 15, 2024.

(51) Int. Cl. B25J 15/06; H01L 21/683; H01L 21/687

(52) U.S. Cl. CPC B25J 15/0616; H01L 21/6838; H01L 21/68707

(57) ABSTRACT

Wafer-handling end effectors configured to selectively engage a wafer via a pressure force and to selectively grip the wafer via a vacuum force, wafer-handling units that include the wafer-handling end effectors, systems that include the wafer-handling units, and methods of utilizing wafer-handling end effectors. The end effectors include a blade that defines a blade vacuum force retention side and an opposed blade pressure force retention side, a gas distribution manifold that extends at least partially within the blade and is in fluid communication with the blade pressure force retention side, and a vacuum distribution manifold that extends at least partially within the blade, is fluidically isolated from the gas distribution manifold within the blade, and is in fluid communication with the blade vacuum force retention side.

### RELATED APPLICATION

This application claims priority to U.S. Provisional Patent Application No. 63/648,060, which was filed on May 15, 2024, and the complete disclosure of which is hereby incorporated by reference.

### FIELD OF THE DISCLOSURE

The present disclosure relates generally to wafer-handling end effectors configured to selectively engage a wafer via a pressure force and to selectively grip the wafer via a vacuum force, wafer-handling units that include the wafer-handling end effectors, systems that include the wafer-handling units, and methods of utilizing wafer-handling end effectors.

### BACKGROUND OF THE DISCLOSURE

Wafer-handling end effectors may be utilized by wafer-handling robots to grip, to grab, to lift, and/or to otherwise convey wafers to, from, and/or within semiconductor manufacture, sort, and/or test equipment. Some conventional wafer-handling end effectors are configured to contact an upper surface of wafers within an edge exclusion zone thereof and only may be configured to convey wafers of a specific size, or diameter, such as 100 millimeter (mm) diameter wafers, 200 mm diameter wafers, or 300 mm diameter wafers.

Other conventional wafer-handling end effectors are configured to contact a central region of the wafer that includes integrated circuit devices. Such wafer-handling end effectors may be effective at selectively lifting wafers of a variety of different sizes, or diameters; however, these wafer-handling end effectors only may be utilized with certain wafers, with specific sides of the wafers, under certain conditions, and/or at certain steps during the manufacture of the integrated circuit devices.

It may be desirable for a given wafer-handling robot to convey wafers of different sizes, to selectively lift the wafers from the upper surface without contacting any integrated circuit devices formed on the wafers, and also to selectively lift the wafers from a lower surface thereof. However, conventional wafer-handling end effectors cannot be utilized in this manner. Thus, there exists a need for improved wafer-handling end effectors configured to selectively engage a wafer via a pressure force and to selectively grip the wafer via a vacuum force, for improved wafer-handling units that include the wafer-handling end effectors, for improved systems that include the wafer-handling units, and for improved methods of utilizing wafer-handling end effectors.

### SUMMARY OF THE DISCLOSURE

Wafer-handling end effectors configured to selectively engage a wafer via a pressure force and to selectively grip the wafer via a vacuum force, wafer-handling units that include the wafer-handling end effectors, systems that include the wafer-handling units, and methods of utilizing wafer-handling end effectors. The end effectors include a blade that defines a blade vacuum force retention side and an opposed blade pressure force retention side, a gas distribution manifold that extends at least partially within the blade and is in fluid communication with the blade pressure force retention side, and a vacuum distribution manifold that extends at least partially within the blade, is fluidically isolated from the gas distribution manifold within the blade, and is in fluid communication with the blade vacuum force retention side.

The wafer-handling units include a wafer-handling robot and the end effector. The end effector is operatively attached to the wafer-handling robot via a blade mounting structure of the blade.

The systems include a chuck that defines a support surface configured to support the wafer and the wafer-handling unit. The wafer-handling unit is configured to selectively position the wafer on the support surface and to selectively remove the wafer from the support surface.

The methods include contacting a blade of the end effector with a surface extension of the end effector and attaching the surface extension to the blade. The methods also include positioning the end effector proximate a surface of the wafer and supplying a pressurized gas stream to a gas distribution manifold of the blade to engage the wafer via the pressure force.

### BRIEF DESCRIPTION OF THE DRAWINGS

FIG. 1 is a schematic top view illustrating examples of systems that include wafer-handling units that include wafer-handling end effectors, according to the present disclosure.

FIG. 2 is a schematic side view illustrating examples of the systems of FIG. 1.

FIG. 3 is an illustration of an example of a profile view of a top side of a blade of a wafer-handling end effector, according to the present disclosure.

FIG. 4 illustrates an example of the blade of FIG. 3 selectively gripping a wafer via a vacuum force.

FIG. 5 is an alternative profile view illustrating a bottom side of the blade of FIGS. 3-4.

FIG. 6 illustrates a blade vacuum force retention side of the blade of FIGS. 3-5.

FIG. 7 illustrates a blade pressure force retention side of the blade of FIGS. 3-6.

FIG. 8 illustrates the blade of FIGS. 3-7 as viewed from the blade vacuum force retention side and with the blade being transparent to expose structures of a gas distribution manifold and a pressure distribution manifold that are at least partially defined by the blade.

FIG. 9 is an illustration of an example of a profile view of a wafer-handling end effector that includes the blade of FIGS. 3-8 and an attached surface extension.

FIG. 10 illustrates the wafer-handling end effector of FIG. 9 selectively gripping a wafer via a pressure force.

FIG. 11 is an alternative profile view of the wafer-handling end effector of FIG. 10.

FIG. 12 is a fragmentary, cross-sectional view illustrating an example of a wafer-handling end effector according to the present disclosure.

FIG. 13 illustrates an extension pressure force retention side of the surface extension of FIGS. 9-11.

FIG. 14 is a profile view of the surface extension of FIG. 13.

FIG. 15 illustrates an example of an extension pressure force retention side of another surface extension, according to the present disclosure.

FIG. 16 is a profile view of the surface extension of FIG. 15.

FIG. 17 is a flowchart depicting examples of methods of utilizing a wafer-handling end effector to selectively engage a wafer from an upper surface of the wafer via a pressure force, according to the present disclosure.

### DETAILED DESCRIPTION AND BEST MODE OF THE DISCLOSURE

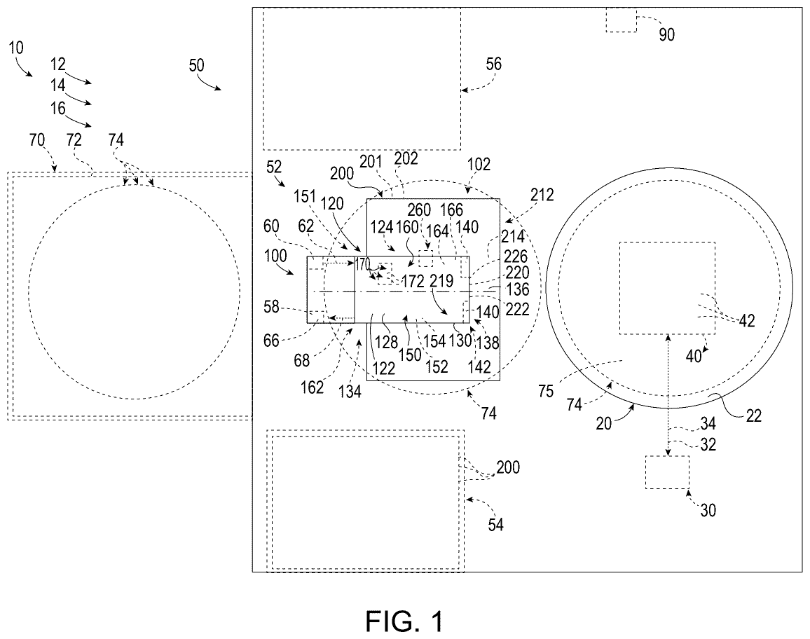

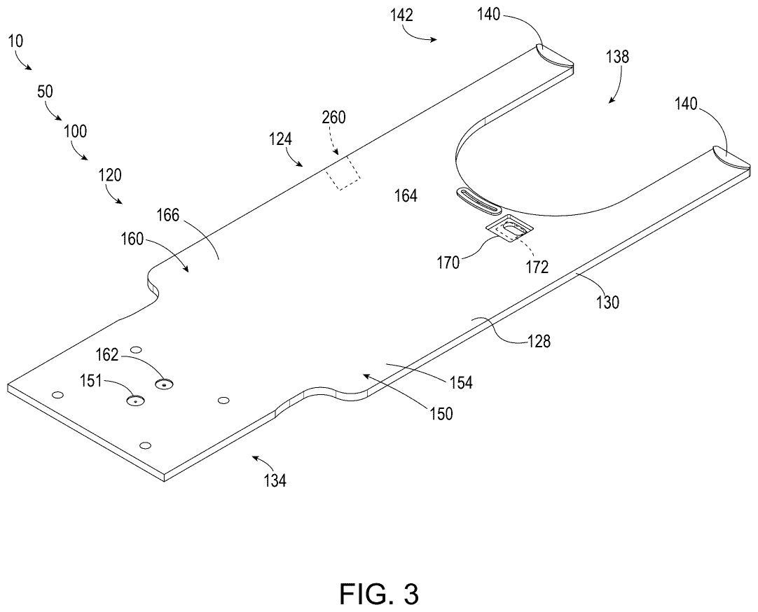

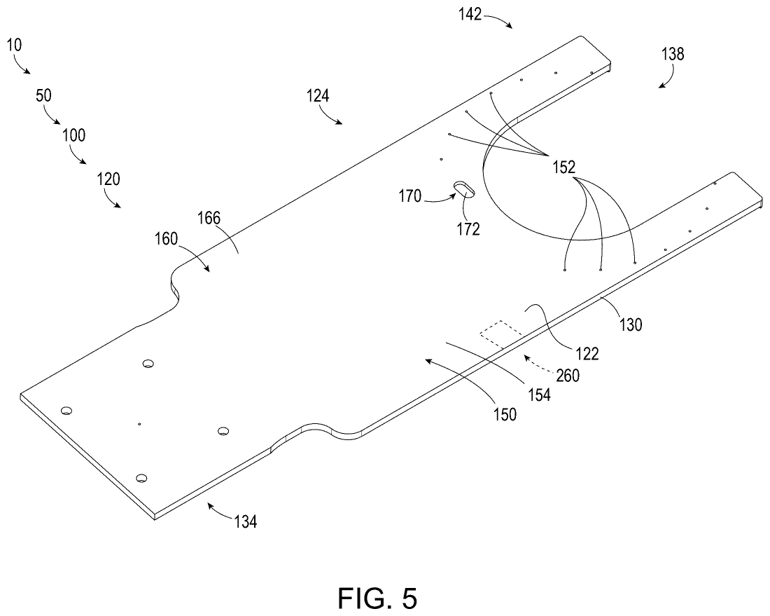

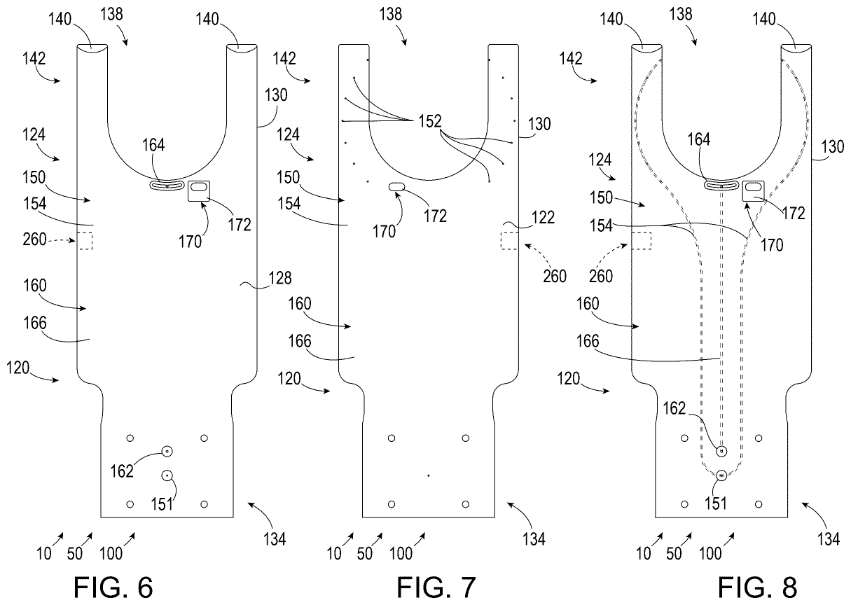

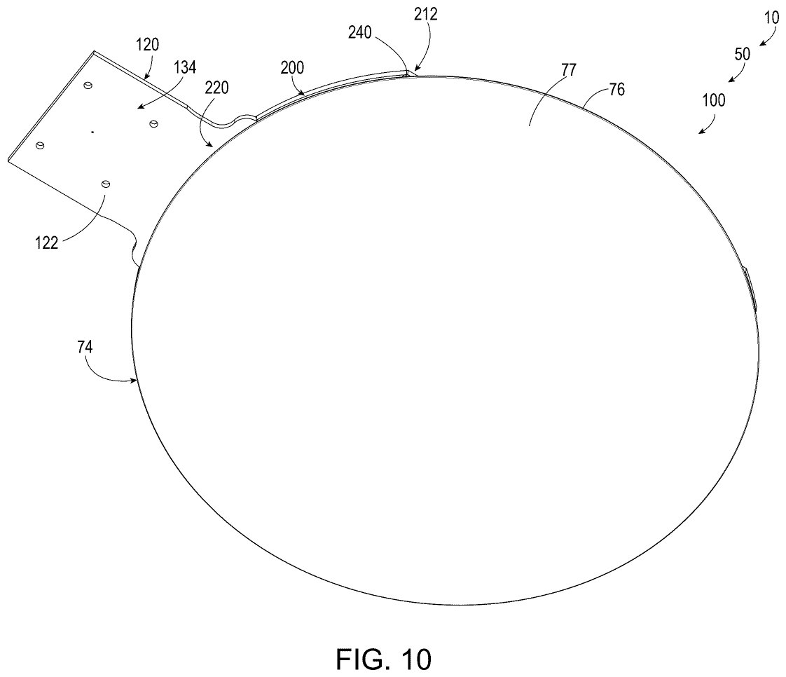

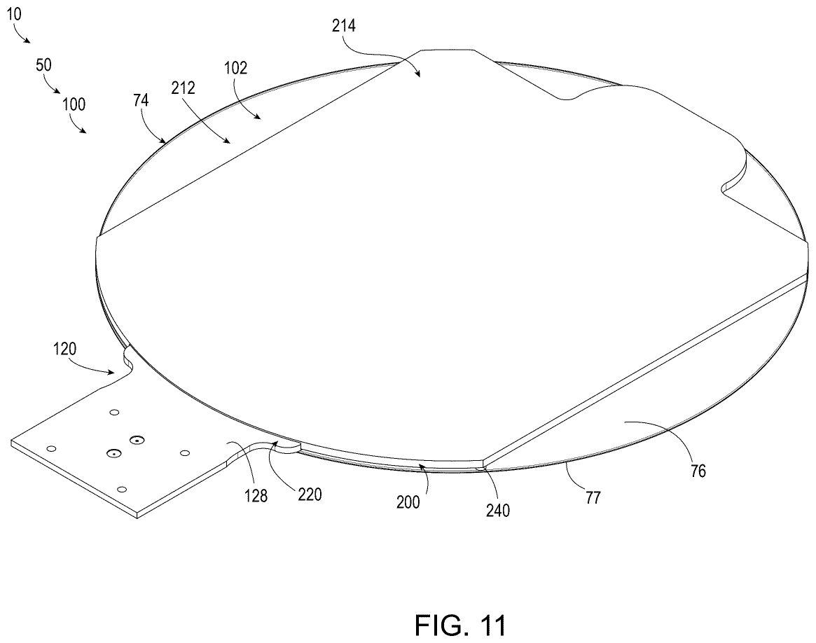

FIGS. 1-17 provide examples of systems 10, of wafer-handling units 50, of wafer-handling end effectors 100, and/or of methods 300, according to the present disclosure. Elements that serve a similar, or at least substantially similar, purpose are labeled with like numbers in each of FIGS. 1-17, and these elements may not be discussed in detail herein with reference to each of FIGS. 1-17. Similarly, all elements may not be labeled in each of FIGS. 1-17, but reference numerals associated therewith may be utilized herein for consistency. Elements, components, and/or features that are discussed herein with reference to one or more of FIGS. 1-17 may be included in and/or utilized with any of FIGS. 1-17 without departing from the scope of the present disclosure.

In general, elements that are likely to be included in a particular embodiment are illustrated in solid lines, while elements that may be optional are illustrated in dashed lines. However, elements that are shown in solid lines may not be essential to all embodiments and, in some embodiments, may be omitted without departing from the scope of the present disclosure.

FIGS. 1-16 illustrate examples of wafer-handling end effectors 100 and/or components thereof, according to the present disclosure. Additional examples of components and/or features of wafer-handling end effectors are disclosed in U.S. Patent Application Publication No. 2024/0190019, which was filed on Nov. 10, 2023, and the complete disclosure of which is hereby incorporated by reference.

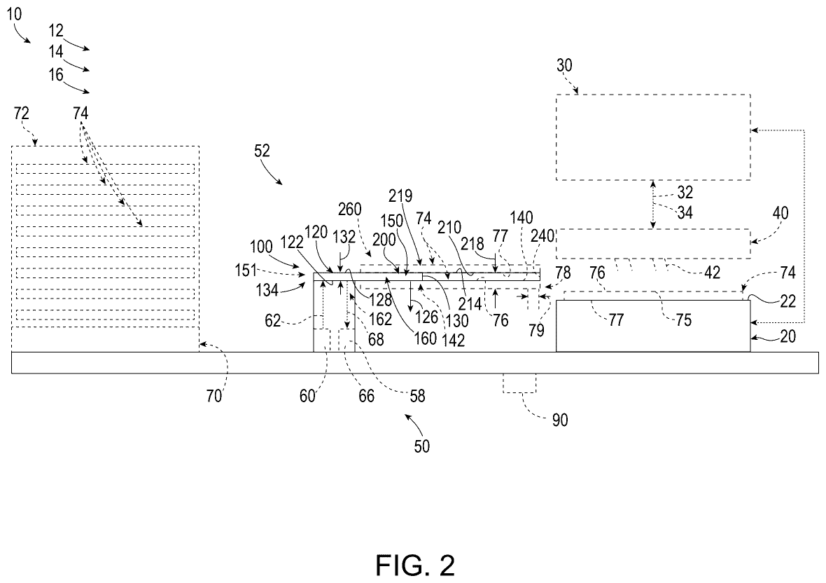

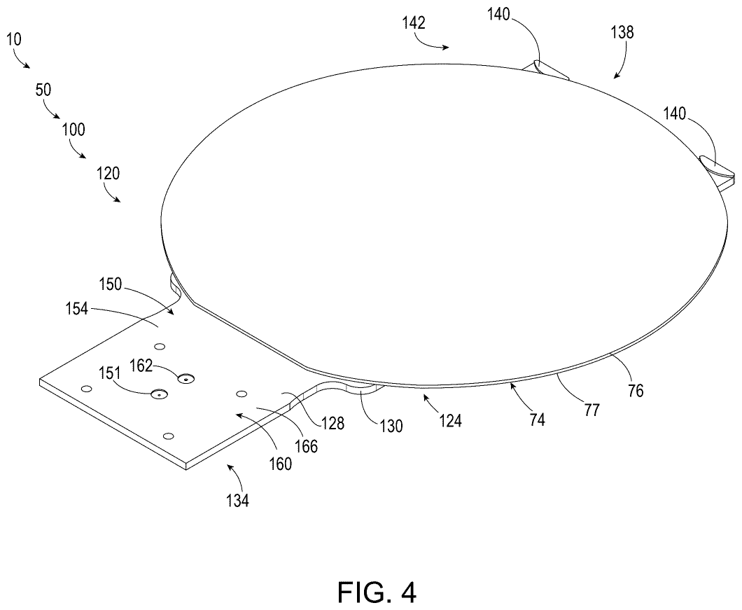

Wafer-handling end effectors 100, which also may be referred to herein as end effectors 100, may be configured to selectively engage, engage with, and/or attach to a wafer 74 via a pressure force, as illustrated in FIGS. 1-2, and 10-11. In some examples, this may include selective engagement with an upper surface 76 of the wafer, as illustrated in FIGS. 2 and 10-11. End effectors 100 also may be configured to selectively grip and/or attach to wafer 74 via a vacuum force, as illustrated in FIGS. 1-2 and 4. In some examples, this may include selectively gripping a lower surface 77 of the wafer, as illustrated in FIGS. 2 and 4.

End effectors 100 include a blade 120. Blade 120 defines a blade pressure force retention side 122 and a blade vacuum force retention side 128. End effectors 100 also include a gas distribution manifold 150 that may extend at least partially within blade 120 and/or that may be in fluid communication with blade pressure force retention side 122. End effectors 100 also include a vacuum distribution manifold 160 that may extend at least partially within blade 120 and/or may be in fluid communication with blade vacuum force retention side 128.

End effectors 100 according to the present disclosure may include and/or be a functionally flexible alternative to conventional end effectors. As an example, during operative use of end effectors 100, and as discussed in more detail herein, blade vacuum force retention side 128 may be positioned proximate and/or in contact with a surface of wafer 74, such as upper surface 76 or lower surface 77, and an applied vacuum 68 may be applied to vacuum distribution manifold 160, as illustrated in FIGS. 1-2. The applied vacuum may generate the vacuum retention force, which may cause the end effector to grip the wafer. This vacuum retention force may permit the end effector to move the wafer and/or may resist relative motion between the end effector and the wafer when the end effector moves the wafer, such as via a static friction force between blade vacuum force retention side 128 of the end effector and the wafer.

Additionally or alternatively, and as discussed in more detail herein, blade pressure force retention side 122 may be positioned proximate, but generally not in contact with, a surface of wafer 74, such as upper surface 76 and/or lower surface 77, and a pressurized gas stream 62 may be applied to gas distribution manifold 150, as also illustrated in FIGS. 1-2. The pressurized gas stream may generate the pressure retention force, such as via the Bernoulli effect, the cyclone effect, and/or other phenomenon that may generate a relatively lower-pressure region between the end effector and the wafer and/or that may generate the pressure retention force. This may cause the end effector to engage with the wafer in a manner that permits the end effector to lift and/or move the wafer without relative motion between the end effector and the wafer.

In some examples, and as discussed in more detail herein, end effector 100 may include a surface extension 200, which may be operatively attached to blade vacuum force retention side 128. Such a configuration may permit end effectors 100 to engage with, to more effectively engage with, and/or to more efficiently engage with wafers 74 of various, or specific, shapes, sizes, and/or diameters. Conventional end effectors simply are incapable of providing the above-described combination of features and/or functionality.

Blade 120 may include any suitable structure that defines blade pressure force retention side 122, that defines blade vacuum force retention side 128, that at least partially defines gas distribution manifold 150, and/or that at least partially defines vacuum distribution manifold 160. In some examples, blade 120 may include and/or be a unitary, a monolithic, and/or a single-piece blade 120. Stated differently and in some such examples, blade pressure force retention side 122, blade vacuum force retention side 128, gas distribution manifold 150, and/or vacuum distribution manifold 160 may be at least partially, or even completely, defined by a single blade body. However, it is also within the scope of the present disclosure that blade 120 may include and/or be a multi-piece and/or a composite blade 120.

Blade 120 may have and/or define any suitable relative orientation between blade pressure force retention side 122 and blade vacuum force retention side 128. As an example, the blade pressure force retention side may extend parallel, or at least substantially parallel, to the blade vacuum force retention side.

Blade 120 may include and/or define a blade mounting structure 134. Blade mounting structure 134 may be configured to facilitate operative attachment of blade 120 to a wafer-handling unit 50 and/or to a wafer-handling robot 52 of the wafer-handling unit. Examples of blade mounting structure 134 include a fastener, a coupler, a clasp, and/or a fastener-receiving region.

Blade 120 may include and/or be an elongate blade that defines a longitudinal, or elongate, axis 136, as illustrated in FIG. 1. Longitudinal axis 136 may extend from blade mounting structure 134 of the blade and to, into, and/or through a blade-wafer overlap region 124 of the blade, as illustrated in FIGS. 1 and 3-8. Blade-wafer overlap region 124 may have and/or define any suitable shape. As examples, the blade-wafer overlap region may include and/or be an arcuate blade-wafer overlap region, an at least partially U-shaped blade-wafer overlap region, and/or an at least partially polygonal-shaped blade-wafer overlap region.

Blade 120 may have and/or define a blade edge 130, which may extend between blade vacuum force retention side 128 and blade pressure force retention side 122. The blade edge may define an extension-receiving region 138 of blade 120, which may be shaped, sized, and/or configured to receive, or to be received within, surface extension 200, when utilized.

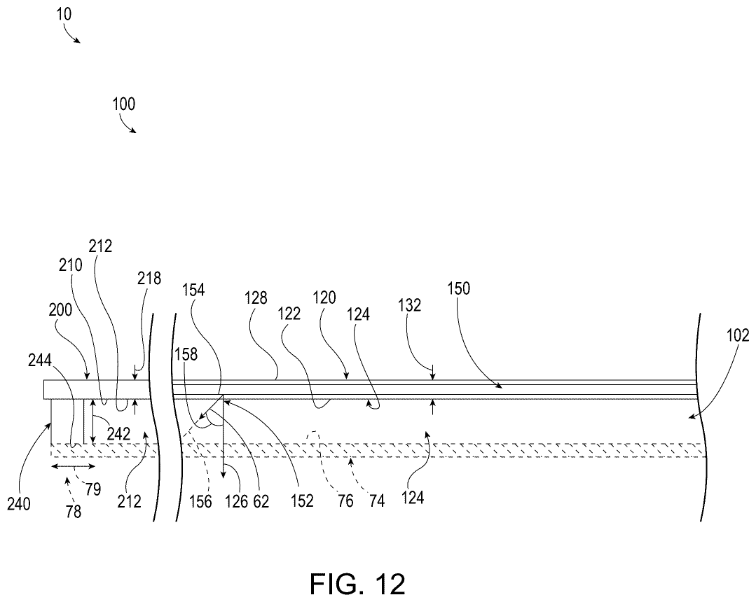

Blade 120 may have and/or define a blade thickness 132, as illustrated in FIGS. 2 and 12. Blade thickness 132 also may be referred to herein as and/or may be an average blade thickness and/or may be measured and/or defined between blade vacuum force retention side 128 and blade pressure force retention side 122. Examples of blade thickness 132 include at least 0.5 millimeters (mm), at least 0.75 mm, at least 1 mm, at least 1.25 mm, at least 1.5 mm, at least 1.75 mm, at least 2 mm, at least 2.5 mm, at least 3 mm, at least 3.5 mm, or at least 4 mm, at most 8 mm, at most 7 mm, at most 6 mm, at most 5 mm, at most 4.5 mm, at most 4 mm, at most 3.5 mm, at most 3 mm, at most 2.5 mm, and/or at most 2 mm.

Blade pressure force retention side 122 may include any suitable structure that may be defined by blade 120 and/or that may be in fluid communication with gas distribution manifold 150. In some examples, and as illustrated in FIG. 2, blade pressure force retention side 122 may include and/or be a lower, or a vertically lower, side of blade 120. Stated differently, blade pressure force retention side 122 may be lower, or vertically lower, relative to blade vacuum force retention side 128. In some examples, blade pressure force retention side 122 may include and/or be a planar, an at least substantially planar, and/or an at least partially planar blade pressure force retention side 122.

Gas distribution manifold 150 may include any suitable structure that may extend at least partially within blade 120, that may be in fluid communication with blade pressure force retention side 122, and/or that may be configured to convey pressurized gas stream 62 to the blade pressure force retention side. As an example, gas distribution manifold 150 may include a plurality of apertures 152 that may be defined within and/or on blade pressure force retention side 122, as illustrated in FIGS. 1, 5, 7, 9, and 12. Apertures 152 may be arranged in a circular, an at least substantially circular, and/or an at least partially circular shape and/or relative orientation, such as may be defined on blade pressure force retention side 122. As illustrated in FIG. 12, gas distribution manifold 150 may be configured to provide pressurized gas stream 62 to blade pressure force retention side 122 via apertures 152.

As another example, gas distribution manifold 150 may include a gas inlet port 151, as illustrated in FIGS. 1-4, 6, and 8. Gas inlet port 151 may be configured to receive pressurized gas stream 62. As another example, gas distribution manifold 150 may include a fluid conduit 154, examples of which are illustrated in FIGS. 1-8, and 12. Fluid conduit 154 may extend between gas inlet port 151 and apertures 152 and/or may be configured to provide the pressurized gas stream to the apertures and/or from the gas inlet port to the apertures.

As illustrated in FIGS. 2 and 12, blade pressure force retention side 122 may define a blade pressure force retention side normal direction 126. As illustrated in FIG. 12, gas distribution manifold 150 may include a plurality of fluid conduits 154. With continued reference to FIG. 12, apertures 152 may extend from corresponding fluid conduits 154, and each fluid conduit 154 may define a corresponding fluid flow axis 156, which may be orientated at a corresponding flow angle 158 relative to the blade pressure force retention side normal direction. Examples of flow angle 158 include at least 30 degrees, at least 35 degrees, at least 40 degrees, at least 45 degrees, at least 50 degrees, at least 55 degrees, at least 60 degrees, at most 80 degrees, at most 75 degrees, at most 70 degrees, at most 65 degrees, and/or at most 60 degrees. With this in mind, the corresponding fluid flow axis 156 of the plurality of fluid conduits 154 may be arranged and/or may extend along a conic, or at least partially conic, surface.

Blade vacuum force retention side 128 may include any suitable structure that may be defined by blade 120 and/or that may be in fluid communication with vacuum distribution manifold 160. In some examples, and as illustrated in FIG. 2, blade vacuum force retention side 128 may include and/or be an upper, or a vertically upper, side of blade 120. In some examples, blade vacuum force retention side 128 may include and/or be a planar, an at least substantially planar, and/or an at least partially planar blade vacuum force retention side 128.

In some examples, and as illustrated in FIGS. 1-4, 6, and 8, blade 120 may include a plurality of wafer-positioning projections 140, which may extend from blade vacuum force retention side 128. In some such examples, wafer-positioning projections 140 may extend from a blade mounting structure-distal end 142 of blade 120. In some such examples, blade-wafer overlap region 124 may be positioned between, or at least partially between, blade mounting structure 134 and wafer-positioning projections 140. In some such examples, each wafer-positioning projection may be configured to contact a corresponding edge region of wafer 74. Such a configuration may permit wafer-positioning projections 140 to position, to precisely position, to locate, and/or to retain wafer 74 on and/or relative to end effector 100, blade 120, and/or blade vacuum force retention side 128, such as when the wafer is gripped by the vacuum force.

The plurality of wafer-positioning projections may include any suitable number of wafer-positioning projections. As an example, and as illustrated, the plurality of wafer-positioning projections may include two, or exactly two, wafer-positioning projections. Such a configuration may permit precise positioning of the wafer with respect to the end effector without over-constraining the wafer.

Vacuum distribution manifold 160 may include any suitable structure that may extend at least partially within blade 120, that may be in fluid communication with blade vacuum force retention side 128, and/or that may be configured to apply the applied vacuum to the blade vacuum force retention side and/or between the wafer and the blade vacuum force retention side. As an example, vacuum distribution manifold 160 may include a vacuum inlet port 162, as illustrated in FIGS. 1-4, 6, and 8. The vacuum inlet port may be at least partially defined by blade 120, and/or on blade vacuum force retention side 128 thereof. Vacuum distribution manifold 160 may be configured to provide applied vacuum 68 to blade vacuum force retention side 128 via and/or utilizing vacuum inlet port 162.

As another example, vacuum distribution manifold 160 may include a vacuum outlet port 164, as illustrated in FIGS. 1, 3, 6, and 8. The vacuum outlet port may be at least partially defined by blade 120, such as in blade-wafer overlap region 124 of blade 120. As another example, vacuum distribution manifold 160 may include a vacuum distribution conduit 166, as illustrated in FIGS. 1 and 3-8. The vacuum distribution conduit may be at least partially defined by blade 120. Vacuum distribution conduit 166 may extend and/or provide fluid communication between vacuum inlet port 162 and vacuum outlet port 164, as illustrated in FIG. 8.

As perhaps best illustrated in FIGS. 1, 3, and 5-9, blade 120 may include at least one wafer presence sensor opening 170. The wafer presence sensor opening may be defined within blade-wafer overlap region 124. Stated differently, and when the end effector selectively lifts the wafer, the wafer may extend across wafer presence sensor opening 170. A wafer presence sensor 172 may be positioned at least partially within and/or proximate wafer presence sensor opening 170, may be configured to detect when the wafer extends across the wafer presence sensor opening, and/or may be configured to detect the presence of the wafer via the wafer presence sensor opening. Stated differently, the wafer presence sensor may be configured to detect the wafer when the end effector selectively lifts the wafer.

In some examples, blade 120 may include a plurality of wafer presence sensor openings 170 and/or a plurality of wafer presence sensors 172. Such a configuration may permit and/or facilitate detection of the presence, or absence, of wafers of various sizes and/or detection of the size of the wafer that is engaged and/or gripped by the wafer-handling end effector. Examples of the wafer presence sensor include an optical sensor, a capacitive sensor, a magnetic sensor, a near field communication sensor, a contact sensor, an electrical contact sensor, and/or a temperature sensor.

In some examples, the wafer presence sensor may be configured to detect the presence, or absence, of the wafer on either, or both, sides of the wafer-handling end effector. In particular, the wafer presence sensor may be configured to detect the presence, or absence, of a corresponding wafer that is engaged via the pressure force, that is engaged on blade pressure force retention side 122, that is gripped via the vacuum force, and/or that is gripped on blade vacuum force retention side 128.

As illustrated in FIGS. 1-2 and 9-16, and as discussed, end effector 100 may include surface extension 200. Surface extension 200 may permit end effectors 100 to engage with, or to more efficiently engage with, wafers 74 utilizing the pressure force. Additionally or alternatively, and as discussed in more detail herein, end effectors 100 may include and/or may be utilized with a plurality of different, differently shaped, and/or differently sized surface extensions 200, with each of the surface extensions being shaped and/or sized to engage with a correspondingly shaped and/or sized wafer via the pressure force.

Surface extension 200 may define an extension pressure force retention side 210 and an extension attachment region 219. Extension pressure force retention side 210 may extend away from blade 120 and/or may extend at least partially around blade pressure force retention side 122. Extension attachment region 219 may extend across blade vacuum force retention side 128 of blade 120. Extension attachment region 219 may be configured to permit and/or to facilitate selective attachment of surface extension 200 to blade 120. This selective attachment may be accomplished in any suitable manner. As an example, selective application of the vacuum force may be utilized to selectively attach the surface extension to the blade. Alternatively, selective cessation of the vacuum force may be utilized to permit selective separation of the surface extension from the blade.

As another example, the selective attachment may be performed utilizing a suitable attachment mechanism 260, as illustrated in FIGS. 1-3, 5-9, and 13-16. Examples of the attachment mechanism include a clip, a clamp, a fastener, a magnet, an electromagnet, and/or an adhesive. In such examples, selective activation of the attachment mechanism may be utilized to selectively attach the surface extension to the blade and/or selective deactivation of the attachment mechanism may be utilized to permit selective separation of the surface extension from the blade. The selective activation of the attachment mechanism also may be referred to herein as and/or may be selective actuation, selective attachment, and/or selective engagement. Similarly, the selective deactivation of the attachment mechanism also may be referred to herein as selective deactuation, selective detachment, and/or selective disengagement.

Blade 120 and/or surface extension 200 may be formed and/or defined from any suitable material and/or materials. As an example, blade 120 may be defined by a blade material and surface extension 200 may be defined by an extension material. The blade material may be the same as the extension material. Alternatively, the blade material may differ from the extension material. Examples of the blade material and/or of the extension material include a metallic material, a polymeric material, an organic material, an inorganic material, a composite material, and/or a ceramic material.

Surface extension 200 may define an extension thickness, or an average extension thickness, 218, as illustrated in FIGS. 2 and 12. Extension thickness 218 may be measured in a direction that is perpendicular, or at least substantially perpendicular, to extension pressure force retention side 210. Extension thickness 218 may have and/or define any suitable magnitude. As examples, a ratio of the extension thickness to blade thickness 132 may be at least 1, at least 1.1, at least 1.2, at least 1.3, at least 1.4, at least 1.5, at most 2, at most 1.8, at most 1.6, at most 1.4, at most 1.2, and/or at most 1.

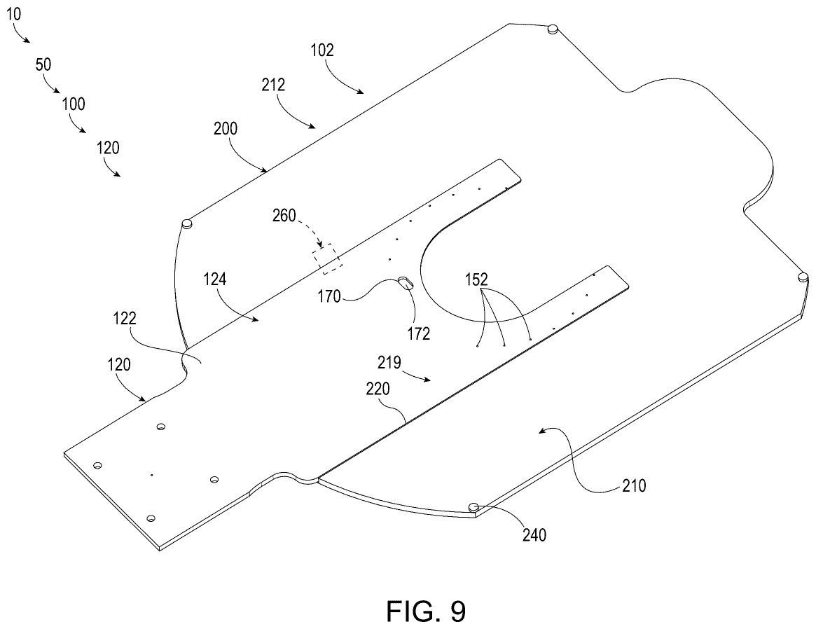

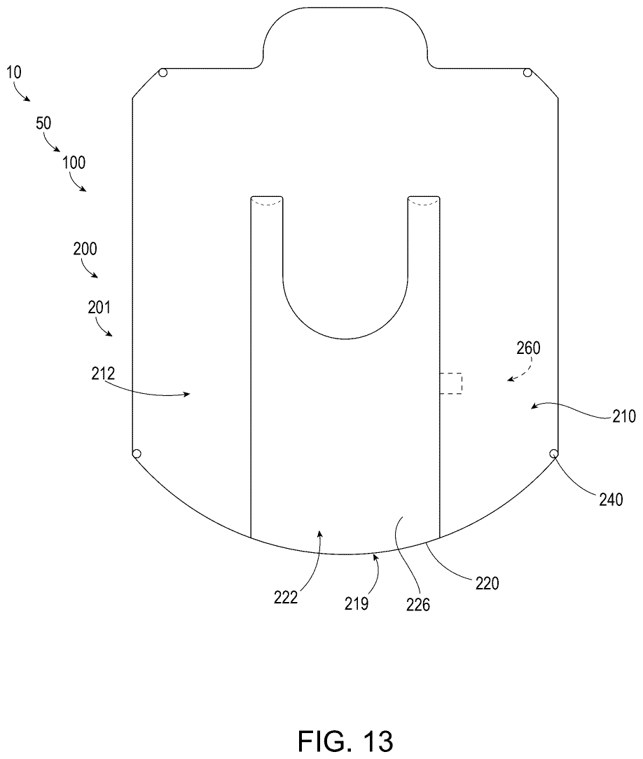

Extension attachment region 219 may include any suitable structure that may be adapted, configured, shaped, sized, and/or constructed to extend across blade vacuum force retention side 128, to precisely position surface extension 200 relative to blade 120, and/or to permit selective attachment of the surface extension to the blade. As an example, extension attachment region 219 may include and/or be a blade-receiving region 220, as illustrated in FIGS. 9-11 and 13-16. In such a configuration, blade 120 may extend and/or may be positioned within the blade-receiving region, as illustrated in FIGS. 9-11. Blade-receiving region 220 may include and/or be a blade-receiving recess 222, as illustrated in FIGS. 13-16. Blade-receiving recess 222 may be defined within and/or by surface extension 200, and extension pressure force retention side 210 may extend away from the blade-receiving recess.

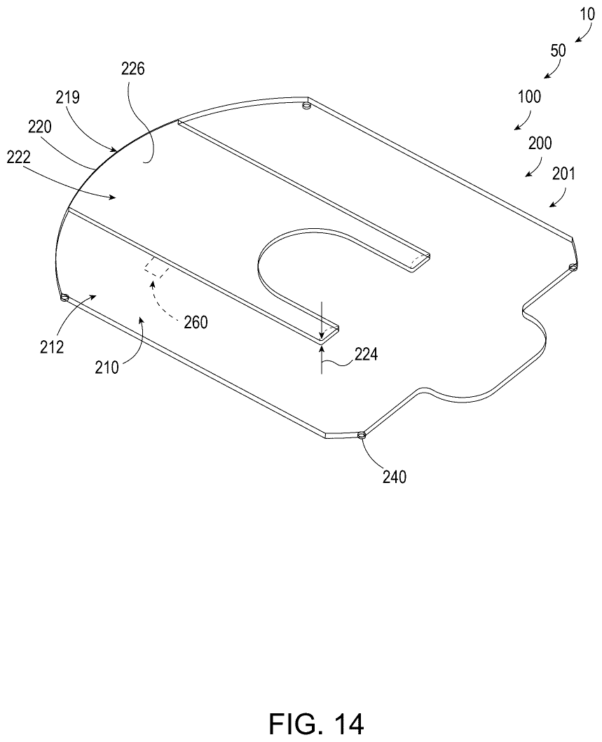

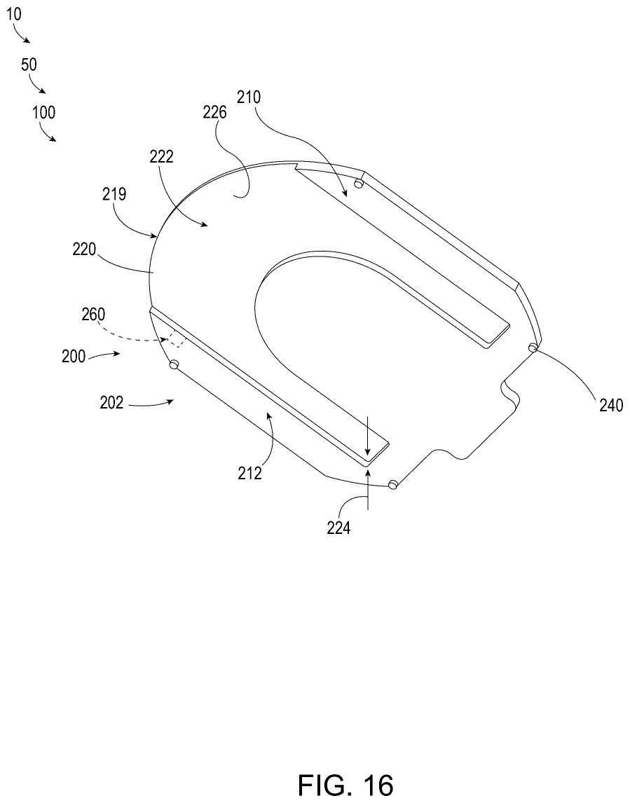

Blade-receiving recess 222 may have and/or define any suitable blade-receiving recess depth 224, as illustrated in FIGS. 14 and 16. As an example, a ratio of blade-receiving recess depth 224 to blade thickness 132 may be at least 0.25, at least 0.3, at least 0.35, at least 0.4, at least 0.45, at least 0.5, at least 0.55, at least 0.6, at least 0.65, at least 0.7, at least 0.75, at least 0.8, at least 0.85, at least 0.9, at least 0.95, at least 1, at most 1, at most 0.95, at most 0.9, at most 0.85, at most 0.8, at most 0.75, at most 0.7, at most 0.65, at most 0.6, at most 0.55, at most 0.5, at most 0.45, and/or at most 0.4. In some examples, blade pressure force retention side 122 may project from extension pressure force retention side 210.

Blade-receiving region 220 additionally or alternatively may define a vacuum-receiving surface 226, as illustrated in FIGS. 13-16. Vacuum-receiving surface 226 may be configured to receive the applied vacuum from the blade vacuum force retention side of the blade, to contact the blade vacuum force retention side of the blade, and/or to define a face-to-face contact with the blade vacuum force retention side of the blade.

Blade-receiving region 220 may have and/or define any suitable shape. As an example, the shape of the blade-receiving region may mirror and/or may correspond to a shape of blade 120. Such a configuration may permit and/or facilitate an accurate, a precise, and/or a repeatable relative orientation between the blade and the surface extension when the surface extension is selectively attached to the blade. Additional examples of the shape of the blade-receiving region include an arcuate blade-receiving region, an at least partially U-shaped blade-receiving region, and/or an at least partially polygonal-shaped blade-receiving region. In some examples, blade-receiving region 220 may be shaped to at least partially or even completely, receive blade-wafer overlap region 124 of blade 120, as illustrated in FIG. 9.

Extension pressure force retention side 210 may include and/or be any suitable structure that may extend away from blade 120 and/or that may extend at least partially around blade 120. In some examples, extension pressure force retention side 210 may be a planar, or at least substantially planar, extension pressure force retention side. In some examples, the extension pressure force retention side may be coplanar, or at least substantially coplanar, with blade pressure force retention side 122. In some examples, the extension pressure force retention side may extend parallel, or at least substantially parallel, to the blade pressure force retention side.

Surface extension 200 may have and/or define an exposed extension side 214. Exposed extension side 214 may be opposed to and/or may extend parallel, or at least substantially parallel, to extension pressure force retention side 210 and/or extension attachment region 219. In some examples, exposed extension side 214 may be a planar, at least partially planar, or at least substantially planar exposed extension side.

Surface extension 200 may include at least three projecting regions 240, as illustrated in FIGS. 2 and 9-16. In some examples, surface extension 200 may include, or include exactly, three, four, five, or six projecting regions 240. Projecting regions 240 may extend and/or project from extension pressure force retention side 210 and/or may be configured to physically contact upper surface 76 of wafer 74 when the end effector selectively engages the wafer via the pressure force, as illustrated in FIG. 12. Stated differently, projecting regions 240 may project toward wafer 74 when the end effector selectively engages the wafer via the pressure force.

The at least three projecting regions may be symmetrically positioned about longitudinal axis 136 of blade 120. Such a configuration may permit and/or facilitate even distribution of contact forces among the projecting regions and the wafer.

Projecting regions 240 may be configured to physically contact wafer 74 within an edge exclusion zone 78 of the wafer, as illustrated in FIGS. 2 and 12. Edge exclusion zone 78 may be defined within an annular region of the wafer that is within a threshold exclusion distance 79 of an outer perimeter of the wafer. Examples of the threshold exclusion distance include at most 2 mm, at most 3 mm, at most 4 mm, and at most 5 mm.

As perhaps best illustrated in FIG. 12, projecting regions 240 may project a projection distance 242 from extension pressure force retention side 210 of surface extension 200. Because end effector 100 utilizes positive air flow from gas distribution manifold 150 to generate the pressure force that engages the wafer, the wafer naturally may be suspended, or may float, a float distance from the end effector, with this float distance being defined by a variety of parameters, including the surface area of overall overlap region 102, the weight of the wafer, and the flow rate of the positive air flow (i.e., pressurized gas streams 62). Stated differently, end effector 100 may be configured to lift wafer 74 without direct physical contact between blade pressure force retention side 122 and the wafer and/or without direct physical contact between extension pressure force retention side 210 and the wafer, with the potential exception of contact between the wafer and projecting regions 240 within edge exclusion zone 78, as discussed.

With this in mind, projection distance 242 may be selected to be greater than this float distance. As such, the pressure force may pull the wafer into contact with projecting regions 240, such as within edge exclusion zone 78 of wafer 74, thereby providing a static friction force between a projection end 244 of the projecting regions and the wafer. This static friction force may resist sliding motion between the end effector and the wafer and/or may retain the wafer on the end effector as the end effector moves within the system. Examples of the projection distance include at least 0.1 mm, at least 0.2 mm, at least 0.3 mm, at least 0.4 mm, at least 0.5 mm, at least 0.6 mm, at least 0.7 mm, at least 0.8 mm, at least 0.9 mm, at least 1 mm, at most 1.5 mm, at most 1.4 mm, at most 1.3 mm, at most 1.2 mm, at most 1.1 mm, at most 1 mm, at most 0.9 mm, at most 0.8 mm, at most 0.7 mm, at most 0.6 mm, and/or at most 0.5 mm.

When end effector 100 selectively engages wafer 74 via the pressure force, projecting regions 240 may be configured to resist sliding motion relative to the wafer and/or between the wafer and the end effector. This resistance to sliding motion may be via the static friction force between the wafer and a projection end 244 of each projecting region 240, as illustrated in FIG. 12. Projection end 244 may have and/or define any suitable shape and/or relative orientation. As an example, projection ends 244 may be planar or at least substantially planar. As another example, projection ends 244 may be coplanar, or at least substantially coplanar, with one another.

As discussed, end effectors 100 may be configured to engage wafers 74 of various shapes, sizes, and/or diameters, via the pressure force. In addition, end effectors 100 may be adapted, configured, and/or customized for a given wafer shape, wafer size, and/or wafer diameter. As an example, end effector 100 may include a plurality of surface extensions 200, with each surface extension 200 being configured to be individually and selectively attached to blade 120 and individual and selectively separated from blade 120 via a corresponding extension attachment region 219.

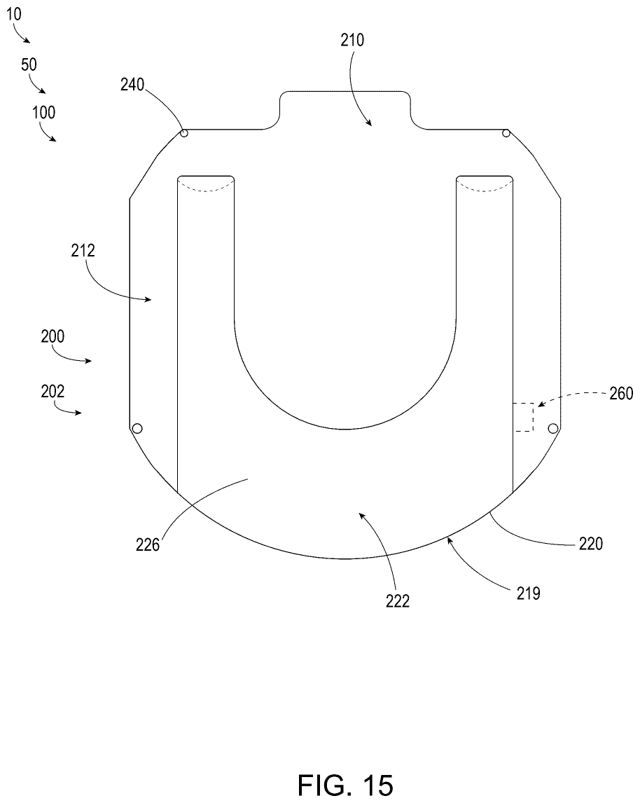

As an example, the plurality of surface extensions 200 may include a first surface extension 201, as illustrated in FIGS. 13-14, and a second surface extension 202, as illustrated in FIGS. 15-16. In such a configuration, end effector 100 may be configured to permit selective attachment and/or selective separation of one, or only one, surface extension 200, such as first surface extension 201 or second surface extension 202, to blade 120 at a given time. Stated differently, blade 120 may be configured to be utilized with a single surface extension 200 at a given point in time; however, different surface extensions 200 may be utilized with blade 120 at different times.

The first surface extension may define a first surface extension shape, while the second surface extension may define a second surface extension shape that differs from the first surface extension shape. As an example, the first surface extension may be sized, shaped, and/or configured to lift a first wafer with a first wafer shape, a first wafer size, and/or a first wafer diameter, such as 300 mm, and the second surface extension may be sized, shaped, and/or configured to lift a second wafer with a second wafer shape, a second wafer size, and/or a second wafer diameter, such as 200 mm, that differs from the respective first wafer shape, first wafer size, and/or first wafer diameter. As another example, the first surface extension may be sized, shaped, and/or configured to lift a round wafer, while the second surface extension may be sized, shaped, and/or configured to lift a polygonal wafer and/or a square wafer.

As discussed, projecting regions 240 may be configured to physically contact the upper surface of the wafer within the edge exclusion zone of the wafer. With this in mind, the first surface extension may include at least three first projecting regions, the second surface extension may include at least three second projecting regions, and a relative orientation of the at least three first projecting regions may differ from a relative orientation of the at least three second projecting regions. As an example, the relative orientation of the at least three first projecting regions may be such that the at least three first projecting regions contact a 300 mm wafer within a corresponding 300 mm wafer edge exclusion zone, while the relative orientation of the at least three second projecting regions may be such that the at least three second projecting regions contact a 200 mm wafer within a corresponding 200 mm wafer edge exclusion zone.

Stated differently, and for round, or at least substantially round wafers, the at least three first projecting regions may be arranged to contact an annular surface with an outer diameter of 300 mm and a width defined by the threshold exclusion zone distance. In contrast, the at least three second projecting regions may be arranged to contact an annular surface with an outer diameter of 200 mm and a width defined by the threshold exclusion zone distance. Wafers with outer diameters of 200 mm and 300 mm are discussed herein as examples, and it is within the scope of the present disclosure that end effectors 100 may be configured to lift wafers with other wafer shapes, wafer sizes, and/or wafer diameters and/or that the at least three projecting regions 240 may be configured to contact corresponding edge exclusion zones of wafers with other wafer shapes, wafer sizes, and/or wafer diameters. Examples of such other wafer sizes and/or wafer diameters include sizes and/or diameters of, or of nominally, 25 mm, 50 mm, 75 mm, 100 mm, 125 mm, 150 mm, 200 mm, 300 mm, and/or 450 mm.

The first surface extension may define a first extension pressure force retention side 210 with a first wafer-facing extension surface area, and the second surface extension may define a second extension pressure force retention side 210 with a second wafer-facing extension surface area. The second wafer-facing extension surface area may differ from the first wafer-facing extension surface area. In particular, and in the example of FIGS. 13-16, the second wafer-facing extension surface area may be less than the first wafer-facing extension surface area, thereby permitting end effector 100, when configured with first surface extension 201 of FIGS. 13-14 to engage with relatively larger wafers via the pressure force when compared to when configured with second surface extension 202 of FIGS. 15-16.

As discussed, blade pressure force retention side 122 may define blade-wafer overlap region 124. In addition, extension pressure force retention side 210 may define an extension-wafer overlap region 212, as illustrated in FIGS. 1 and 9-16. Blade-wafer overlap region 124 and extension-wafer overlap region 212 together may define an overall overlap region 102 for end effector 100, which may be configured to face toward, and overlap with, upper surface 76 of wafer 74 when the end effector selectively lifts the wafer and is illustrated in FIGS. 1, 9, 11, and 12. To facilitate reliable generation of the pressure force, and thereby to permit reliable lifting of the wafer by the end effector, the shape, size, and/or area of overall overlap region 102 may correspond to, be based upon, and/or be proportional to the shape, size, diameter, and/or area of upper surface 76 of wafer 74. The ability of blade 120 to accept surface extensions 200 of varying shapes and/or sizes permits the shape, size, and/or area of overall overlap region 102 to be adjusted as needed and/or based upon the shape and/or size of wafer 74, thereby permitting and/or facilitating lifting wafers of correspondingly different sizes, shapes, and/or diameters, by end effector 100. As examples, and as discussed, end effector 100 may be configured to lift round, at least substantially round, or at least partially round wafers, square, at least substantially square, or at least partially square wafers, and/or polygonal, at least substantially polygonal, or at least partially polygonal wafers.

Overall overlap region 102 may define an overall overlap surface area that may be a threshold overlap fraction of a wafer surface area of the upper surface of the wafer. Stated differently, end effector 100 may overlap with the threshold overlap fraction of the upper surface of the wafer. Examples of the threshold overlap fraction include at least 50%, at least 55%, at least 60%, at least 65%, at least 70%, at least 75%, at least 80%, at least 85%, at most 95%, at most 92.5%, at most 90%, at most 87.5%, at most 85%, at most 82.5%, and/or at most 80%. The threshold overlap surface area and/or the threshold overlap fraction may be selected to provide a desired normal force between projecting regions 240 and the upper surface of the wafer when the end effector selectively lifts the wafer. As an example, the threshold overlap surface area and/or the threshold overlap fraction may be increased to increase the normal force and/or may be decreased to decrease the normal force.

Blade-wafer overlap region 124 may have and/or define a blade-wafer overlap region area that may be a threshold blade overlap region fraction of the overall overlap area. Examples of the threshold blade overlap region fraction include at least 25%, at least 30%, at least 35%, at least 40%, at least 45%, at least 50%, at least 55%, at least 60%, at least 65%, at least 70%, at least 75%, at least 80%, at least 85%, at most 95%, at most 90%, at most 85%, at most 80%, at most 75%, at most 70%, at most 65%, at most 60%, at most 55%, at most 50%, at most 45%, and/or at most 40%. The threshold blade overlap region fraction may vary depending upon a size of surface extension 200.

Returning to FIGS. 1-2, and as discussed, end effectors 100 may be utilized with a wafer-handling unit 50 that also includes a wafer-handling robot 52. More specifically, end effector 100 may be operatively attached to the wafer-handling robot, such as via blade-mounting structure 134 of blade 120. Wafer-handling unit 50 may be configured to position wafers 74 within a system 10 that includes the wafer-handling unit. Examples of wafer-handling robot 52 include a robotic arm, a motor, a servo motor, a stepper motor, and/or a motor controller. Examples of systems 10 include a metrology system 12, a probe system 14, and/or a wafer processing system 16.

Wafer-handling unit 50 and/or end effector 100 thereof may include a plurality of surface extensions 200, as illustrated in FIG. 1. The plurality of surface extensions 200, which also may be referred to herein as and/or may be a spaced-apart stack of surface extensions 200, may be contained and/or housed within an extension depot 54 of the wafer-handling unit, as also illustrated in FIG. 1. Within the extension depot, a space between adjacent surface extensions 200 of the spaced-apart stack of surface extensions may be sufficient to permit blade 120 to be positioned between the adjacent surface extensions, such as to permit and/or facilitate attachment of a selected surface extension to the blade.

As discussed in more detail herein, each surface extension 200 may be configured to be individually and/or selectively attached to, engaged with, separated from, and/or disengaged from blade 120, such as via application and/or cessation of the vacuum force and/or via activation and/or deactivation of attachment mechanism 260. In such a configuration, at least one surface extension 200 may be differently shaped and/or sized relative to at least one other surface extension 200. Such a configuration may permit and/or facilitate gripping of differently shaped and/or sized wafers 74 with end effector 100 and via a pressure force, as discussed in more detail herein.

In some such examples, wafer-handling unit 50 may be configured to receive a wafer size input, such as from a controller 90 of systems 10, and to select a corresponding surface extension 200 based, at least in part, on the wafer size input. Stated differently, wafer-handling unit 50 may be configured to select the corresponding surface extension 200 that is shaped and/or sized to engage, via the pressure force, a wafer with a wafer shape and/or wafer size that corresponds to the wafer size input.

In such a configuration, wafer-handling unit 50 further may be configured to contact at least a region of blade vacuum force retention side 128 of blade 120 with extension attachment region 219 of the corresponding surface extension and subsequently to apply the vacuum force and/or actuate attachment mechanism 260 to operatively attach the corresponding surface extension to the blade. Subsequently, the wafer-handling unit may be configured to engage a wafer 74 via the pressure force and from blade pressure force retention side 122 of the blade.

As illustrated in dashed lines in FIG. 1, wafer-handling unit 50 may include an extension detector 56. Extension detector 56 may be configured to detect an orientation of corresponding surface extension 200 that is operatively attached to blade 120. This may include detection of the orientation relative to the blade. Such a configuration may permit and/or facilitate detection of correctly aligned surface extensions and/or of misaligned surface extensions. Additionally or alternatively, extension detector 56 may be configured to detect a shape and/or size of the corresponding surface extension. Such a configuration may permit verification that the correct surface extension has been selected for the provided wafer size input. Examples of extension detector 56 include an optical sensor, a capacitive sensor, an electrical contact between the blade and the surface extension, a camera, and/or a unique identifier, such as a RFID, NFC, and/or QR code.

As illustrated in dashed lines in FIGS. 1-2, wafer-handling unit 50 also may include a pressure detector 58. Pressure detector 58 may be configured to detect a magnitude of the applied vacuum between blade 120 and corresponding surface extension 200, when utilized. Such a configuration may permit and/or facilitate confirmation of attachment, or a desired level of attachment, between the blade and the corresponding surface extension via the vacuum force. As an example, the pressure detector may be configured to confirm that a magnitude of the applied vacuum is greater than a threshold vacuum magnitude, thereby confirming the attachment between the blade and the corresponding surface extension.

The vacuum force may be applied in any suitable manner. As an example, and as illustrated in dashed lines in FIGS. 1-2, wafer-handing unit 50 may include a vacuum source 66. Vacuum source 66 may be configured to supply, or to selectively supply, an applied vacuum 68 to vacuum distribution manifold 160 of blade 120 to generate the vacuum force. Examples of vacuum source 66 include a vacuum pump and/or a blower.

Similarly, the pressure force may be applied in any suitable manner. As an example, and as illustrated in dashed lines in FIGS. 1-2, wafer-handling unit 50 may include a pressurized gas source 60. Pressurized gas source 60 may be configured to selectively supply a pressurized gas stream 62 to gas distribution manifold 150 of blade 120 to generate the pressure force. Examples of pressurized gas source 60 include a pressurized gas tank, a compressor, and/or a blower. Examples of pressurized gas stream 62 include an air stream, a dry air stream, and/or an inert gas stream.

During operation of wafer-handling units 50 and/or of systems 10 that include wafer-handling units 50, the wafer-handling unit may be configured to retrieve wafer 74 from a wafer cassette 72, to position the wafer within the wafer cassette, to position the wafer on a support surface 22 of a chuck 20, and/or to retrieve the wafer from the support surface. With this in mind, end effector 100 may be sized for clearance within the wafer cassette and/or between adjacent wafers that are positioned within the wafer cassette.

The wafer may be retrieved and/or positioned in any suitable manner. As an example, end effector 100 may utilize the vacuum force to grip the wafer. In such examples, blade 120 of end effector 100 may be positioned such that blade vacuum force retention side 128 faces toward the wafer. Subsequently, applied vacuum 68 may be applied to vacuum distribution manifold 160, causing the end effector to grip the wafer via the vacuum force. Also in such examples, the applied vacuum may be ceased to permit and/or facilitate separation of the wafer from the end effector.

As another example, a surface extension 200 that is sized for the wafer shape, size, and/or diameter of the wafer may be operatively attached to blade vacuum force retention side 128 of blade 120, such as via the vacuum force and/or via attachment mechanism 260. Subsequently, end effector 100 may be positioned such that blade pressure force retention side 122 of blade 120 and extension pressure force retention side 210 of surface extension 200 both face toward the wafer. Pressurized gas stream 62 then may be provided to gas distribution manifold 150, causing the end effector to engage the wafer via the pressure force. Subsequently, flow of the pressurized gas stream may be ceased, thereby permitting and/or facilitating separation of the wafer from the end effector.

With continued reference to FIGS. 1-2, systems 10 include wafer-handling units 50 that include wafer-handling end effectors 100, according to the present disclosure. FIG. 2 may include and/or be an additional and/or alternative illustration of systems 10, wafer-handling units 50, and/or end effectors 100 of FIG. 1. Stated differently, FIG. 2 may illustrate the same systems 10, wafer-handling units 50, and/or end effectors 100 as FIG. 1 but may do so from an alternative view and/or angle, thereby permitting and/or facilitating illustration of additional and/or alternative features that may not be readily visible in FIG. 1. With this in mind, any structure, function, and/or feature that is illustrated and/or described herein with reference to FIG. 1 may be included in and/or utilized with FIG. 2 without departing from the scope of the present disclosure. Similarly, any structure, function and/or feature illustrated and/or described herein with reference to FIG. 2 may be included in and/or utilized with FIG. 1 without departing from the scope of the present disclosure.

Systems 10 may be configured to perform an operation on wafer 74 and include chuck 20 and wafer-handling unit 50. Examples of systems 10 are discussed herein. Examples of the operation include a measurement operation, a defect detection operation, a test operation, and/or a process operation.

Chuck 20 defines support surface 22 that is configured to support wafer 74. As illustrated in FIG. 2, support surface 22 of chuck 20 generally faces upward and supports wafer 74 such that an upper surface 76 of the wafer also faces upward and/or such that a lower surface 77 of the wafer faces downward and/or contacts the support surface; however, such a configuration is not required. Examples of chuck 20 include a shielded chuck, an electrically shielded chuck, a vacuum chuck, an electrostatic chuck, and/or a temperature-controlled chuck. Examples of wafer 74 include a semiconductor wafer, a silicon wafer, a type III-V semiconductor wafer, and/or any suitable substrate upon which an integrated circuit device 75 may be formed and/or defined. As discussed in more detail herein, this may include at least partially round, square, and/or polygonal wafers.

Wafer-handling unit 50 may be configured to selectively position wafer 74 on support surface 22. Additionally or alternatively, wafer-handling unit 50 may be configured to selectively remove the wafer from the support surface.

When system 10 includes and/or is probe system 14, wafer 74 may include an integrated circuit device 75. In such examples, probe system 14 may be configured to test the operation of the integrated circuit device.

As an example, and as illustrated in dashed lines in FIGS. 1-2, probe system 14 may include a signal generation and analysis assembly 30. The signal generation and analysis assembly may be configured to generate a test signal 32 and/or to receive a resultant signal 34. Examples of signal generation and analysis assembly 30 include a test signal generator, a function generator, an electrical signal generator, an optical signal generator, a resultant signal receiver, a resultant signal analyzer, an electrical signal detector, an electrical signal analyzer, an optical detector, and/or an optical signal analyzer.

In such examples, probe system 14 also may include a probe assembly 40. Probe assembly 40 may be configured to receive test signal 32 from signal generation and analysis assembly 30 and to provide the test signal to integrated circuit device 75. Additionally or alternatively, probe assembly 40 may be configured to receive resultant signal 34 from integrated circuit device 75 and to provide the resultant signal to the signal generation and analysis assembly. Integrated circuit device 75 may produce and/or generate the resultant signal at least partially responsive to receipt of the test signal.

In some examples of probe systems 14, probe assembly 40 may receive both test signal 32 and resultant signal 34. In other examples of probe systems 14, probe assembly 40 may receive one of test signal 32 and resultant signal 34, while the other of test signal 32 and resultant signal 34 may be conveyed to signal generation and analysis assembly 30 via another structure, such as chuck 20. Probe assembly 40 may include one or more probes 42, examples of which include an electrical probe, a contact probe, an electromagnetic probe, an optical probe, and/or a non-contact probe.

As also illustrated in dashed lines in FIGS. 1-2, systems 10 may include a wafer cassette docking port 70. Wafer cassette docking port 70 may be configured to receive a wafer cassette 72, which may include, contain, and/or house a plurality of wafers 74. Examples of wafer cassette docking port 70 include any suitable port, surface, actuator, and/or receptacle that may be shaped, sized, and/or designed to receive, to detect the presence of, and/or to support wafer cassette 72. Examples of wafer cassette 72 include a suitable container and/or housing that is sized and/or configured to enclose and/or contain wafers 74 and/or a spaced-apart stack of wafers 74, as illustrated in FIG. 2.

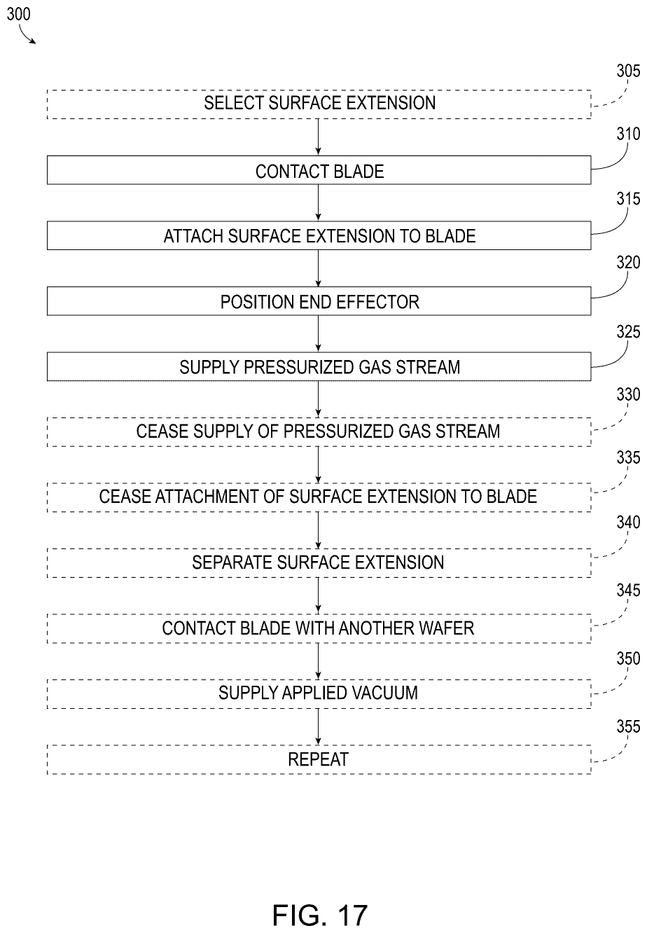

FIG. 17 is a flowchart depicting examples of methods 300 of utilizing a wafer-handling end effector to selectively engage a wafer from an upper surface of the wafer via a pressure force, according to the present disclosure. Examples of the wafer-handling end effectors are disclosed herein with reference to wafer-handling end effectors 100. Examples of the wafer are disclosed herein with reference to wafer 74.

Methods 300 may include selecting a surface extension at 305 and include contacting a blade at 310, attaching a surface extension to the blade at 315, positioning an end effector at 320, and supplying a pressurized gas stream at 325. Methods 300 also may include ceasing supply of the pressurized gas stream at 330, ceasing attachment of the surface extension to the blade at 335, separating the surface extension at 340, contacting the blade with another wafer at 345, supplying an applied vacuum at 350, and/or repeating at 355.

Selecting the surface extension at 305 may include selecting the surface extension from a plurality of surface extensions of, or utilized with, the end effector. The selecting at 305 may be accomplished in any suitable manner. As an example, the selecting at 305 may include determining a shape, size, and/or diameter of the wafer and selecting the surface extension based, at least in part, on the shape, size, and/or diameter of the wafer. Stated differently, the selecting at 305 may include selecting such that the surface extension is shaped and/or sized for the wafer and/or is shaped and/or sized for the shape, size, and/or diameter of the wafer. Examples of the surface extension are disclosed herein with reference to surface extension 200.

The selecting at 305 may be performed with any suitable timing and/or sequence during methods 300. As an example, the selecting at 305 may be performed prior to the contacting at 310.

Contacting the blade at 310 may include contacting the blade of the end effector with a surface extension of the end effector. Examples of the blade are disclosed herein with reference to blade 120. The contacting at 310 may be performed in any suitable manner. As an example, the contacting at 310 may include contacting at least a region of a blade vacuum force retention side of the blade with an extension attachment region of the surface extension. Examples of the blade vacuum force retention side are disclosed herein with reference to blade vacuum force retention side 128. Examples of the extension attachment region are disclosed herein with reference to extension attachment region 219.

The contacting at 310 may be performed with any suitable timing and/or sequence during methods 300. As examples, the contacting at 310 may be performed subsequent to the selecting at 305, prior to the attaching at 315, and/or at least partially concurrently with the attaching at 315.

Attaching the surface extension to the blade at 315 may include defining and/or establishing any suitable attachment force that retains the blade on the surface extension and may be performed in any suitable manner. As an example, the attaching at 315 may include supplying an applied vacuum to a vacuum distribution manifold of the blade. This may include supplying the applied vacuum to attach the surface extension to the blade via a vacuum force and/or generating the vacuum force between the blade vacuum force retention side and the extension attachment region. Examples of the vacuum distribution manifold are disclosed herein with reference to vacuum distribution manifold 160. As another example, the attaching at 315 may include activating an attachment mechanism of the wafer-handling end effector to attach the surface extension to the blade and/or to mechanically couple the surface extension to the blade. Examples of the attachment mechanism are disclosed herein with reference to attachment mechanism 260.

The attaching at 315 may be performed with any suitable timing and/or sequence during methods 300. As examples, the attaching at 315 may be performed subsequent to the contacting at 310 and/or at least partially concurrently with the contacting at 310. As additional examples, methods 300 may include maintaining the attaching at 315, or maintaining attachment of the surface extension to the blade, during the positioning at 320 and/or during the supplying at 325.

Positioning the end effector at 320 may include positioning the end effector proximate a surface, or an upper surface, of the wafer. This may include positioning the end effector such that a blade pressure force retention side of the blade faces toward the surface of the wafer. Additionally or alternatively, the positioning at 320 may include positioning such that an extension pressure force retention side of the surface extension faces toward the surface of the wafer. Examples of the blade pressure force retention side and the extension pressure force retention side are disclosed herein with reference to blade pressure force retention side 122 and extension pressure force retention side 210, respectively.

The positioning at 320 may be performed with any suitable timing and/or sequence during methods 300. As examples, the positioning at 320 may be performed subsequent to and/or at least partially concurrently with the attaching at 315 and/or while the surface extension is attached to the blade. As additional examples, the positioning at 320 may be performed prior to and/or at least partially concurrently with the supplying at 325.

Supplying the pressurized gas stream at 325 may include supplying the pressurized gas stream to a gas distribution manifold of the end effector. This may include supplying the pressurized gas stream to engage the end effector with the wafer via the pressure force. Examples of the gas distribution manifold are disclosed herein with reference to gas distribution manifold 150. The supplying at 325 may be performed in any suitable manner. As an example, the supplying at 325 may include flowing the pressurized gas stream from the blade retention force side, flowing the pressurized gas stream between the blade and the wafer, and/or flowing the pressurized gas stream via a plurality of apertures defined within the blade pressure force retention side.

The supplying at 325 may be performed with any suitable timing and/or sequence during methods 300. As examples, the supplying at 325 may be performed subsequent to and/or at least partially concurrently with the positioning at 320. As another example, the supplying at 325 may be performed during transfer of the wafer utilizing the end effector.

Ceasing supply of the pressurized gas stream at 330 may include ceasing the supplying at 325 and/or ceasing supply of the pressurized gas stream to the gas distribution manifold. Additionally or alternatively, the ceasing at 330 may include ceasing application of the pressure force to the wafer and/or between the wafer and the end effector. Stated differently, the ceasing at 330 may include ceasing engagement between the wafer and the end effector via the pressure force. Stated still differently, the ceasing at 330 may include releasing the wafer from the end effector.

The ceasing at 330 may be performed with any suitable timing and/or sequence during methods 300. As examples, the ceasing at 330 may be performed subsequent to the supplying at 325, subsequent to performing the supplying at 325 for at least a threshold wafer transfer time, and/or subsequent to transferring the wafer utilizing the end effector.

Ceasing attachment of the surface extension to the blade at 335 may include ceasing attachment to permit and/or facilitate the separating at 340 and may be performed in any suitable manner. As an example, the ceasing at 335 may include ceasing supply of the applied vacuum to the vacuum distribution manifold. Additionally or alternatively, the ceasing at 335 may include ceasing application of the vacuum force to the surface extension and/or between the blade and the surface extension. Stated differently, the ceasing at 335 may include ceasing engagement between the blade and the surface extension via the vacuum force. As another example, the ceasing at 335 may include deactivating the attachment mechanism to permit separation of the surface extension from the blade and/or to mechanically decouple the surface extension from the blade. The ceasing at 335 may include releasing the surface extension from the blade and/or permitting separation of the surface extension from the blade, such as during the separating at 340.

The ceasing at 335 may be performed with any suitable timing and/or sequence during methods 300. As examples, the ceasing at 335 may be performed subsequent to transferring the wafer utilizing the end effector, subsequent to the ceasing at 330, prior to the separating at 340, and/or to permit and/or facilitate the separating at 340.

Separating the surface extension at 340 may include separating the surface extension from the blade. This may include establishing a spaced-apart relationship between the surface extension and the blade and/or positioning the surface extension within an extension depot, examples of which are disclosed herein with reference to extension depot 54.

The separating at 340 may be performed with any suitable timing and/or sequence during methods 300. As examples, the separating at 340 may be performed subsequent to the ceasing at 335, prior to the contacting at 345, to facilitate the contacting at 345, prior to the repeating at 355, and/or to facilitate the repeating at 355.

Contacting the blade with another wafer at 345 may include contacting the blade vacuum force retention side of the blade with the other wafer and/or with a surface of the other wafer. This may include contacting the blade with the wafer subsequent to the separating at 340, prior to the supplying at 350, and/or at least partially concurrently with the suppling at 350.

Supplying the applied vacuum at 350 may include supplying the applied vacuum to the vacuum distribution manifold of the blade. This may include supplying the applied vacuum to grip the other wafer with the end effector and/or to permit and/or facilitate transfer of the other wafer utilizing the end effector.

The supplying at 350 may be performed with any suitable timing and/or sequence during methods 300. As examples, the supplying at 350 may be performed subsequent to and/or at least partially concurrently with the contacting at 345.

As discussed in more detail herein, the end effector may include and/or may be configured to be utilized with a plurality of different and/or distinct surface extensions, such as may be sized for a plurality of different and/or distinct wafers and/or wafer shapes, wafer sizes, and/or wafer diameters. As an example, the surface extension may be a first surface extension, the wafer may be a first wafer with a first wafer shape, a first wafer size, and/or a first wafer diameter, and methods 300 further may include configuring the end effector to engage with a second wafer of a second wafer shape, a second wafer size, and/or a second wafer diameter that differs from the respective first wafer shape, first wafer size, and/or first wafer diameter.

With this in mind, and in some examples, methods 300 may include performing the ceasing at 330, such as to permit and/or facilitate separation of the first wafer from the end effector, performing the ceasing at 335, such as to permit and/or facilitate separation of the surface extension from the blade, and performing the separating at 340, such as to separate the surface extension from the blade. The repeating at 355 then may include sequentially repeating the selecting at 305, the contacting at 310, the attaching at 315, the positioning at 320, and/or the supplying at 325 utilizing a second surface extension, which differs from the first surface extension, to engage the second wafer and/or to permit and/or facilitate transfer of the second wafer utilizing the pressure force.

As also discussed in more detail herein, end effectors, according to the present disclosure, additionally or alternatively may be utilized to grip and/or transfer wafers utilizing the vacuum force. With this in mind, and in some examples, methods 300 may include performing the ceasing at 330, such as to permit and/or facilitate separation of the first wafer from the end effector, performing the ceasing at 335, such as to permit and/or facilitate separation of the surface extension from the blade, and performing the separating at 340, such as to separate the surface extension from the blade. Methods 300 then may include performing the contacting at 345 to contact the blade vacuum force retention side of the blade with the wafer or with a different wafer. Methods 300 further may include performing the supplying at 350 to supply the applied vacuum to the vacuum distribution manifold and grip the wafer, or the other wafer, utilizing the vacuum force.

Methods 300 may provide benefits over conventional methods of utilizing conventional end effectors. As an example, methods 300 may permit and/or facilitate performing at least the contacting at 310, the attaching at 315, the positioning at 320, and the supplying at 325 while the blade, or the same blade, is affixed to a wafer-handling robot. Stated differently, methods 300 may be performed without detaching the blade from the wafer-handling robot. As another example, methods 300 may permit and/or facilitate performing at least the contacting at 310, the attaching at 315, the positioning at 320, and the supplying at 325 without first teaching the wafer-handling robot. Stated differently, methods 300 may permit and/or facilitate utilization of the plurality of surface extensions, engaging variously sized wafers utilizing the pressure force, and/or gripping variously sized wafers utilizing the vacuum force without, or without the need to, teach the wafer-handling robot.

As discussed in more detail herein, systems 10 and/or wafer-handling units 50, according to the present disclosure, may include controller 90. It is within the scope of the present disclosure that controller 90 may be adapted, configured, and/or programmed to perform, to direct the systems to perform, and/or to direct the wafer-handling units to perform any suitable step and/or steps of method 300.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entities in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” may mean A alone, B alone, C alone, A and B together, A and C together, B and C together, A, B, and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

As used herein, “at least substantially,” when modifying a degree or relationship, may include not only the recited “substantial” degree or relationship, but also the full extent of the recited degree or relationship. A substantial amount of a recited degree or relationship may include at least 75% of the recited degree or relationship. For example, an object that is at least substantially formed from a material includes objects for which at least 75% of the objects are formed from the material and also includes objects that are completely formed from the material. As another example, a first length that is at least substantially as long as a second length includes first lengths that are within 75% of the second length and also includes first lengths that are as long as the second length.

Illustrative, non-exclusive examples of systems, wafer-handling units, wafer-handling end effectors, and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A wafer-handling end effector configured to selectively engage a wafer, optionally from an upper surface of the wafer, via a pressure force and to selectively grip the wafer, optionally from a lower surface of the wafer, via a vacuum force, the end effector comprising:
a blade that defines a blade vacuum force retention side and an opposed blade pressure force retention side;
a gas distribution manifold that extends at least partially within the blade and is in fluid communication with the blade pressure force retention side; and
a vacuum distribution manifold that extends at least partially within the blade, is fluidically isolated from the gas distribution manifold within the blade, and is in fluid communication with the blade vacuum force retention side.

A2. The end effector of paragraph A1, wherein the blade is at least one of a unitary, a monolithic, and a single-piece blade.

A3. The end effector of any of paragraphs A1-A2, wherein the blade pressure force retention side extends parallel, or at least substantially parallel, to the blade vacuum force retention side.

A4. The end effector of any of paragraphs A1-A3, wherein the blade is an elongate blade that defines a longitudinal axis.

A5. The end effector of paragraph A4, wherein the longitudinal axis extends from a blade mounting structure of the blade and into a blade-wafer overlap region of the blade.

A6. The end effector of any of paragraphs A1-A5, wherein the blade includes a/the blade-wafer overlap region.

A7. The end effector of paragraph A6, wherein the blade-wafer overlap region is at least one of:
(i) an arcuate blade-wafer overlap region;
(ii) an at least partially U-shaped blade-wafer overlap region; and
(iii) an at least partially polygonal-shaped blade-wafer overlap region.

A8. The end effector of any of paragraphs A1-A7, wherein the blade defines a blade edge that extends between the blade vacuum force retention side and the blade pressure force retention side.

A9. The end effector of paragraph A8, wherein the blade edge defines an extension-receiving region of the blade.

A10. The end effector of any of paragraphs A1-A9, wherein the blade defines a blade thickness, or an average blade thickness, between the blade vacuum force retention side and the blade pressure force retention side of at least one of:
(i) at least 0.5 millimeters (mm), at least 0.75 mm, at least 1 mm, at least 1.25 mm, at least 1.5 mm, at least 1.75 mm, at least 2 mm, at least 2.5 mm, at least 3 mm, at least 3.5 mm, or at least 4 mm; and
(ii) at most 8 mm, at most 7 mm, at most 6 mm, at most 5 mm, at most 4.5 mm, at most 4 mm, at most 3.5 mm, at most 3 mm, at most 2.5 mm, or at most 2 mm.

A11. The end effector of any of paragraphs A1-A10, wherein the blade vacuum force retention side includes, or is, an upper side of the blade.

A12. The end effector of any of paragraphs A1-A11, wherein the blade vacuum force retention side is a planar, an at least substantially planar, or an at least partially planar blade vacuum force retention side.

A13. The end effector of any of paragraphs A1-A12, wherein the blade includes a plurality of wafer-positioning projections that extends from the blade vacuum force retention side.

A14. The end effector of paragraph A13, wherein the plurality of wafer-positioning projections extends from a blade mounting structure-distal end of the blade.

A15. The end effector of any of paragraphs A13-A14, wherein a/the blade-wafer overlap region of the blade is positioned between a/the blade mounting structure of the blade and the plurality of wafer-positioning projections.

A16. The end effector of any of paragraphs A13-A15, wherein the plurality of wafer-positioning projections includes two, or exactly two, wafer-positioning projections.

A17. The end effector of any of paragraphs A13-A16, wherein each wafer-positioning projection of the plurality of wafer-positioning projections is configured to contact a corresponding wafer edge region of the wafer to precisely position the wafer with respect to the end effector.

A18. The end effector of any of paragraphs A1-A17, wherein the vacuum distribution manifold includes a vacuum inlet port, which is at least partially defined by the blade.

A19. The end effector of paragraph A18, wherein the vacuum inlet port is defined on the blade vacuum force retention side of the blade.

A20. The end effector of any of paragraphs A18-A19, wherein the vacuum distribution manifold includes a vacuum outlet port, which is at least partially defined by the blade.

A21. The end effector of paragraph A20, wherein the vacuum outlet port is defined within a/the blade-wafer overlap region of the blade.

A22. The end effector of any of paragraphs A20-A21, wherein the vacuum distribution manifold further includes a vacuum distribution conduit, which is at least partially defined by the blade.

A23. The end effector of paragraph A22, wherein the vacuum distribution conduit extends and provides fluid communication between the vacuum inlet port and the vacuum outlet port.

A24. The end effector of any of paragraphs A20-A23, wherein the vacuum distribution manifold is configured to provide an applied vacuum to the blade vacuum force retention side via the vacuum inlet port.

A25. The end effector of any of paragraphs A1-A24, wherein the blade pressure force retention side includes, or is, a lower side of the blade.

A26. The end effector of any of paragraphs A1-A25, wherein the blade pressure force retention side is a planar, an at least substantially planar, or an at least partially planar blade pressure force retention side.

A27. The end effector of any of paragraphs A1-A26, wherein the gas distribution manifold includes a plurality of apertures defined within the blade pressure force retention side.

A28. The end effector of paragraph A27, wherein the plurality of apertures is arranged in a circular, an at least substantially circular, or an at least partially circular shape.

A29. The end effector of any of paragraphs A27-A28, wherein the blade pressure force retention side defines a blade pressure force retention side normal direction, wherein the plurality of apertures extends from a plurality of corresponding fluid conduits, wherein each fluid conduit of the plurality of corresponding fluid conduits defines a corresponding fluid flow axis, and further wherein the corresponding fluid flow axis of each fluid conduit is oriented at a corresponding flow angle relative to the blade pressure force retention side normal direction.

A30. The end effector of paragraph A29, wherein the corresponding flow angle is at least one of:
(i) at least 30 degrees, at least 35 degrees, at least 40 degrees, at least 45 degrees, at least 50 degrees, at least 55 degrees, or at least 60 degrees; and
(ii) at most 80 degrees, at most 75 degrees, at most 70 degrees, at most 65 degrees, or at most 60 degrees.

A31. The end effector of any of paragraphs A29-A30, wherein the corresponding flow angle of each fluid conduit of each aperture extends along an at least partially conic surface.

A32. The end effector of any of paragraphs A27-A31, wherein the gas distribution manifold is configured to provide a pressurized gas stream to the blade pressure force retention side via the plurality of apertures.

A33. The end effector of any of paragraphs A1-A32, wherein the gas distribution manifold is configured such that the wafer-handling end effector selectively engages the wafer via at least one of the Bernoulli effect and the cyclone effect.

A34. The end effector of any of paragraphs A1-A33, wherein the end effector further includes a surface extension, wherein the surface extension defines:
(i) an extension pressure force retention side that extends away from the blade and at least partially around the blade pressure force retention side, and
(ii) an extension attachment region that extends across the blade vacuum force retention side of the blade and is configured to permit selective attachment of the surface extension to the blade, optionally via at least one of application of the vacuum force and activation of an attachment mechanism, and selective separation of the surface extension from the blade, optionally via at least one of cessation of the vacuum force and deactivation of the attachment mechanism.

A35. The end effector of paragraph A34, wherein the blade is defined by a blade material, and further wherein the surface extension is defined by an extension material, optionally wherein the extension material is the same as the blade material, and further optionally wherein the extension material differs from the blade material.

A36. The end effector of paragraph A35, wherein the blade material is at least one of a metallic blade material, a polymeric blade material, an organic blade material, an inorganic blade material, a composite blade material, and a ceramic blade material.

A37. The end effector of any of paragraphs A35-A36, wherein the extension material is at least one of a metallic extension material, a polymeric extension material, an organic extension material, an inorganic extension material, a composite extension material, and a ceramic extension material.

A38. The end effector of any of paragraphs A34-A37, wherein the surface extension defines an extension thickness, or an average extension thickness, as measured in a direction that is perpendicular to the extension pressure force retention side.

A39. The end effector of paragraph A38, wherein a ratio of the extension thickness to a/the blade thickness of the blade is at least one of:
(i) at least 1, at least 1.1, at least 1.2, at least 1.3, at least 1.4, or at least 1.5; and
(ii) at most 2, at most 1.8, at most 1.6, at most 1.4, at most 1.2, or at most 1.

A40. The end effector of any of paragraphs A34-A39, wherein the extension attachment region defines a blade-receiving region, and further wherein the blade extends within the blade-receiving region.

A41. The end effector of paragraph A40, wherein the blade-receiving region includes a blade-receiving recess defined within the surface extension, and further wherein the extension pressure force retention side extends away from the blade-receiving recess.

A42. The end effector of any of paragraphs A40-A41, wherein the blade-receiving region defines a vacuum-receiving surface configured to at least one of:
(i) receive an/the applied vacuum from the blade vacuum force retention side of the blade;
(ii) contact the blade vacuum force retention side of the blade; and
(iii) define a face-to-face contact with the blade vacuum force retention side of the blade.

A43. The end effector of any of paragraphs A41-A42, wherein the blade-receiving recess defines a blade-receiving recess depth, wherein the blade defines a/the blade thickness, and further wherein a ratio of the blade-receiving recess depth to the blade thickness is at least one of:
(i) at least 0.25, at least 0.3, at least 0.35, at least 0.4, at least 0.45, at least 0.5, at least 0.55, at least 0.6, at least 0.65, at least 0.7, at least 0.75, at least 0.8, at least 0.85, at least 0.9, at least 0.95, or at least 1; and
(ii) at most 1, at most 0.95, at most 0.9, at most 0.85, at most 0.8, at most 0.75, at most 0.7, at most 0.65, at most 0.6, at most 0.55, at most 0.5, at most 0.45, or at most 0.4.

A44. The end effector of any of paragraphs A40-A43, wherein the blade pressure force retention side projects from the extension pressure force retention side.

A45. The end effector of any of paragraphs A40-A44, wherein the blade-receiving region includes at least one of:
(i) an arcuate blade-receiving region;
(ii) an at least partially U-shaped blade-receiving region; and
(iii) an at least partially polygonal-shaped blade-receiving region.

A46. The end effector of any of paragraphs A40-A45, wherein the blade-receiving region is shaped to at least partially receive a/the blade-wafer overlap region of the blade.

A47. The end effector of any of paragraphs A34-A46, wherein the extension pressure force retention side is coplanar, or at least substantially coplanar, with the blade pressure force retention side.

A48. The end effector of any of paragraphs A34-A47, wherein the extension pressure force retention side is a planar extension pressure force retention side.

A49. The end effector of any of paragraphs A34-A48, wherein the extension pressure force retention side extends parallel, or at least substantially parallel, to the blade pressure force retention side.

A50. The end effector of any of paragraphs A34-A49, wherein the surface extension defines an exposed extension side that is opposed to at least one of the extension pressure force retention side and the extension attachment region.

A51. The end effector of paragraph A50, wherein the exposed extension side is a planar, or at least substantially planar, exposed extension side.

A52. The end effector of any of paragraphs A34-A51, wherein the surface extension includes at least three projecting regions that project from the extension pressure force retention side.

A53. The end effector of paragraph A52, wherein the at least three projecting regions are configured to physically contact the upper surface of the wafer when the end effector selectively engages the wafer.

A54. The end effector of any of paragraphs A52-A53, wherein the at least three projecting regions includes three, four, five, or six projecting regions.

A55. The end effector of any of paragraphs A52-A54, wherein the at least three projecting regions project toward the wafer when the end effector selectively engages the wafer via the pressure force.

A56. The end effector of any of paragraphs A52-A55, wherein the at least three projecting regions are symmetrically positioned about a/the longitudinal axis of the blade.

A57. The end effector of any of paragraphs A52-A56, wherein the at least three projecting regions are configured to physically contact the upper surface of the wafer within an edge exclusion zone of the wafer.

A58. The end effector of paragraph A57, wherein the edge exclusion zone of the wafer is defined within an annular region that is within a threshold exclusion distance of an outer perimeter of the wafer, optionally wherein the threshold exclusion distance is at most 2 mm, at most 3 mm, at most 4 mm, or at most 5 mm.

A59. The end effector of any of paragraphs A52-A58, wherein the at least three projecting regions project a threshold projection distance from the extension pressure force retention side, optionally wherein the threshold projection distance is at least one of:
(i) at least 0.1 mm, at least 0.2 mm, at least 0.3 mm, at least 0.4 mm, at least 0.5 mm, at least 0.6 mm, at least 0.7 mm, at least 0.8 mm, at least 0.9 mm, or at least 1 mm; and
(ii) at most 1.5 mm, at most 1.4 mm, at most 1.3 mm, at most 1.2 mm, at most 1.1 mm, at most 1 mm, at most 0.9 mm, at most 0.8 mm, at most 0.7 mm, at most 0.6 mm, or at most 0.5 mm.

A60. The end effector of any of paragraphs A52-A59, wherein, when the end effector selectively engages the wafer, the at least three projecting regions are configured to resist sliding motion relative to the wafer via a static friction force between the wafer and a projection end of each of the at least three projecting regions.

A61. The end effector of any of paragraphs A52-A60, wherein a/the projection end of each of the at least three projecting regions is a planar, or at least substantially planar, projection end.

A62. The end effector of any of paragraphs A52-A61, wherein a/the projection end of each of the at least three projecting regions is coplanar with a projection end of each other of the at least three projecting regions.

A63. The end effector of any of paragraphs A34-A62, wherein the end effector includes a plurality of surface extensions, and further wherein each surface extension of the plurality of surface extensions is configured to be individually and selectively attached to the blade and individually and selectively separated from the blade via a corresponding extension attachment region.

A64. The end effector of any of paragraphs A34-A63, wherein the surface extension is a first surface extension, and further wherein the end effector includes a second surface extension.

A65. The end effector of paragraph A64, wherein the end effector is configured to permit selective attachment and selective separation of one, or only one, of the first surface extension and the second surface extension to the blade at a given time.

A66. The end effector of any of paragraphs A64-A65, wherein the first surface extension defines a first surface extension shape, and further wherein the second surface extension defines a second surface extension shape that differs from the first surface extension shape.

A67. The end effector of any of paragraphs A64-A66, wherein the first surface extension is sized to permit the end effector to selectively engage a first wafer with a first wafer shape, a first wafer size, and/or a first wafer diameter, and further wherein the second surface extension is sized to permit the end effector to selectively engage a second wafer with a second wafer shape, a second wafer size, and/or a second wafer diameter that differs from the respective first wafer shape, first wafer size, and/or first wafer diameter.

A68. The end effector of any of paragraphs A64-A67, wherein the first surface extension is sized to permit the end effector to selectively engage one of a 25 mm wafer, a 50 mm wafer, a 75 mm wafer, a 100 mm wafer, a 125 mm wafer, a 150 mm wafer, a 200 mm wafer, a 300 mm wafer, or a 450 mm wafer, and further wherein the second surface extension is sized to permit the end effector to selectively engage another of the 25 mm wafer, the 50 mm wafer, the 75 mm wafer, the 100 mm wafer, the 125 mm wafer, the 150 mm wafer, the 200 mm wafer, the 300 mm wafer, or the 450 mm wafer.

A69. The end effector of any of paragraphs A64-A68, wherein the first surface extension includes at least three first projecting regions, wherein the second surface extension includes at least three second projecting regions, and further wherein a relative orientation of the at least three first projecting regions differs from a relative orientation of the at least three second projecting regions.

A70. The end effector of paragraph A69, wherein the relative orientation of the at least three first projecting regions is such that the at least three first projecting regions contact one of a/the 25 mm wafer, a/the 50 mm wafer, a/the 75 mm wafer, a/the 100 mm wafer, a/the 125 mm wafer, a/the 150 mm wafer, a/the 200 mm wafer, a/the 300 mm wafer, or a/the 450 mm wafer within a corresponding wafer edge exclusion zone, and further wherein the relative orientation of the at least three second projecting regions is such that the at least three second projecting regions contact another of the 25 mm wafer, the 50 mm wafer, the 75 mm wafer, the 100 mm wafer, the 125 mm wafer, the 150 mm wafer, the 200 mm wafer, the 300 mm wafer, or the 450 mm wafer within a corresponding wafer edge exclusion zone.

A71. The end effector of any of paragraphs A34-A70, wherein the blade pressure force retention side defines a/the blade-wafer overlap region, wherein the extension pressure force retention side defines an extension-wafer overlap region, wherein the blade-wafer overlap region and the extension-wafer overlap region together define an overall overlap region of the end effector, and further wherein the overall overlap region is configured to face toward, and overlap with, the upper surface of the wafer when the end effector selectively engages the wafer via the pressure force.

A72. The end effector of paragraph A71, wherein an overall overlap surface area of the overall overlap region is a threshold overlap fraction of a wafer surface area of the upper surface of the wafer, wherein the threshold overlap fraction is at least one of:
(i) at least 50%, at least 55%, at least 60%, at least 65%, at least 70%, at least 75%, at least 80%, or at least 85%; and
(ii) at most 95%, at most 92.5%, at most 90%, at most 87.5%, at most 85%, at most 82.5%, or at most 80%.

A73. The end effector of any of paragraphs A71-A72, wherein a/the overall overlap surface area of the overall overlap region is selected to provide a desired normal force between the at least three projecting regions and the upper surface of the wafer when the end effector selectively engages the wafer.

A74. The end effector of any of paragraphs A71-A73, wherein the blade-wafer overlap region has a blade-wafer overlap region area that is a threshold blade overlap region fraction of an/the overall overlap surface area, and further wherein the threshold blade overlap region fraction is at least one of:
(i) at least 25%, at least 30%, at least 35%, at least 40%, at least 45%, at least 50%, at least 55%, at least 60%, at least 65%, at least 70%, at least 75%, at least 80%, or at least 85%; and
(ii) at most 95%, at most 90%, at most 85%, at most 80%, at most 75%, at most 70%, at most 65%, at most 60%, at most 55%, at most 50%, at most 45%, or at most 40%.

A75. The end effector of any of paragraphs A1-A74, wherein the blade further includes a/the blade mounting structure configured to facilitate operative attachment of the blade to a wafer-handling robot.

A76. The end effector of any of paragraphs A1-A75, wherein the blade further includes a wafer presence sensor opening defined within a/the blade-wafer overlap region of the blade.

A77. The end effector of paragraph A76, wherein the end effector further includes a wafer presence sensor configured to detect the wafer when the end effector selectively engages the wafer via at least one, and optionally either, of the pressure force and the vacuum force.

A78. The end effector of any of paragraphs A1-A77, wherein the end effector is sized for clearance within a wafer cassette that is configured to contain a plurality of wafers.

A79. The end effector of any of paragraphs A1-A78, wherein the end effector is configured to engage the wafer via the pressure force without direct physical contact between the blade pressure force retention side and the wafer.

A80. The end effector of any of paragraphs A1-A79, wherein the end effector is configured to engage the wafer via the pressure force without direct physical contact between the blade pressure force retention side and the wafer outside an/the edge exclusion zone of the wafer.

A81. The end effector of any of paragraphs A1-A80, wherein the end effector includes the wafer.

B1. A wafer-handling unit, comprising:
a wafer-handling robot; and
the end effector of any of paragraphs A1-A81, wherein the end effector is operatively attached to the wafer-handling robot via a/the blade mounting structure of the blade.

B2. The wafer-handling unit of paragraph B1, wherein the wafer-handling unit further includes a/the plurality of surface extensions, and further wherein each surface extension of the plurality of surface extensions is configured to be individually and selectively attached to the blade and individually and selectively separated from the blade via a corresponding extension attachment region.

B3. The wafer-handling unit of paragraph B2, wherein at least one surface extension of the plurality of surface extensions is differently sized relative to at least one other surface extension of the plurality of surface extensions.

B4. The wafer-handling unit of any of paragraphs B2-B3, wherein the wafer-handling unit is configured to receive a wafer size input and to select a corresponding surface extension of the plurality of surface extensions based, at least in part, on the wafer size input.

B5. The wafer-handling unit of paragraph B4, wherein the wafer-handling unit further is configured to contact at least a region of the blade vacuum force retention side with the extension attachment region of the corresponding surface extension, optionally wherein the wafer-handling unit subsequently is configured to apply the vacuum force to operatively attach the corresponding surface extension to the blade, and further optionally wherein the wafer-handling unit further is configured to actuate an/the attachment mechanism to operatively attach the corresponding surface extension to the blade.

B6. The wafer-handling unit of paragraph B5, wherein the wafer-handling unit further is configured to engage the wafer via the pressure force and from the blade pressure force retention side.

B7. The wafer-handling unit of any of paragraphs B2-B6, wherein the wafer-handling unit further includes an extension depot configured to contain the plurality of surface extensions, optionally wherein the plurality of surface extensions defines a spaced-apart stack of surface extensions within the extension depot, and further wherein a space between adjacent surface extensions within the spaced-apart stack of surface extensions is sufficient to permit the blade to be positioned between the adjacent surface extensions.

B8. The wafer-handling unit of any of paragraphs B2-B7, wherein the wafer-handling unit further includes an extension detector configured to at least one of:
(i) detect an orientation of a/the corresponding surface extension that is operatively attached to the blade; and
(ii) detect a size of the corresponding surface extension that is operatively attached to the blade.

B9. The wafer-handling unit of any of paragraphs B2-B8, wherein the wafer-handling unit further includes a pressure detector configured to detect a magnitude of an/the applied vacuum between the blade and a/the corresponding surface extension, optionally wherein the wafer-handling unit is configured to confirm that the magnitude of the applied vacuum is greater than a threshold vacuum magnitude to verify desired attachment between the blade and the corresponding surface extension.

B10. The wafer-handling unit of any of paragraphs B1-B9, wherein the wafer-handling unit further includes a vacuum source configured to selectively supply an/the applied vacuum to the vacuum distribution manifold.

B11. The wafer-handling unit of any of paragraphs B1-B10, wherein the wafer-handling unit further includes a pressurized gas source configured to selectively supply a pressurized gas stream to the gas distribution manifold.

C1. A system configured to perform an operation on a wafer, the system comprising:
a chuck that defines a support surface configured to support the wafer; and
the wafer-handling unit of any of paragraphs B1-B11, wherein the wafer-handling unit is configured to selectively position the wafer on the support surface and to selectively remove the wafer from the support surface.

C2. The system of paragraph C1, wherein the system includes at least one of:
(i) a metrology system;
(ii) a probe system; and
(iii) a wafer processing system.

C3. The system of any of paragraphs C1-C2, wherein the process operation includes at least one of:
(i) a measurement operation;
(ii) a test operation; and
(iii) a process operation.

C4. The system of any of paragraphs C1-C3, wherein the system includes a probe system, wherein the wafer includes an integrated circuit device, and further wherein the probe system includes:
(i) a signal generation and analysis assembly configured to generate a test signal and to receive a resultant signal; and
(ii) a probe assembly configured to at least one of:
   a. receive the test signal from the signal generation and analysis assembly and provide the test signal to the integrated circuit device; and
   b. receive the resultant signal from the integrated circuit device and provide the resultant signal to the signal generation and analysis assembly.

C5. The system of any of paragraphs C1-C4, wherein the probe system further includes a wafer cassette docking port configured to receive a wafer cassette that includes the wafer.

C6. The system of paragraph C5, wherein the wafer-handling unit is configured to at least one of:
(i) transfer the wafer from the wafer cassette to the chuck; and
(ii) transfer the wafer from the chuck to the wafer cassette.

D1. A method of utilizing a wafer-handling end effector configured to engage a wafer, optionally from an upper surface of the wafer, via a pressure force, the method comprising:
contacting a blade of the end effector with a surface extension of the end effector;
attaching the surface extension to the blade, optionally by supplying an applied vacuum to a vacuum distribution manifold of the blade to attach the surface extension to the blade via a vacuum force, and further optionally by activating an attachment mechanism of the wafer-handling end effector;
positioning the end effector proximate a surface of the wafer; and
supplying a pressurized gas stream to a gas distribution manifold of the blade to engage the wafer via the pressure force.

D2. The method of paragraph D1, wherein the contacting includes contacting at least a region of a blade vacuum force retention side of the blade with an extension attachment region of the surface extension.

D3. The method of any of paragraphs D1-D2, wherein the supplying the applied vacuum includes generating the vacuum force between the blade vacuum force retention side and the extension attachment region.

D4. The method of any of paragraphs D1-D3, wherein the method includes maintaining the applied vacuum during the positioning and also during the supplying the pressurized gas stream.

D5. The method of any of paragraphs D1-D4, wherein the positioning includes positioning the end effector such that a blade pressure force retention side of the blade faces toward the surface, or the upper surface, of the wafer.

D6. The method of any of paragraphs D1-D5, wherein the supplying the pressurized gas stream includes flowing the pressurized gas stream from the blade vacuum force retention side via a plurality of apertures defined within the blade vacuum force retention side.

D7. The method of any of paragraphs D1-D6, wherein, prior to the contacting, the method further includes determining at least one of a wafer shape, a wafer size, and a wafer diameter of the wafer and selecting, from a plurality of surface extensions of the end effector, the surface extension such that the surface extension is sized for that at least one of the wafer shape, the wafer size, and the wafer diameter.

D8. The method of any of paragraphs D1-D7, wherein the surface extension is a first surface extension, wherein the wafer is a first wafer, and further wherein, subsequent to the supplying the pressurized gas stream for at least a threshold wafer transfer time, the method further includes:
ceasing supply of the pressurized gas stream;
ceasing attachment of the surface extension to the blade;
separating the first surface extension from the blade; and
sequentially repeating the contacting, the attaching the surface extension, the positioning, and the supplying the pressurized gas stream utilizing a second surface extension, which differs from the first surface extension, to engage a second wafer of at least one of a second wafer diameter, a second wafer shape, and a second wafer size, that differs from at least one of a first wafer diameter, a first wafer shape, and a first wafer size of the first wafer.

D9. The method of any of paragraphs D1-D8, wherein subsequent to the supplying the pressurized gas stream for at least a threshold wafer transfer time, the method further includes:
ceasing the attachment of the surface extension;
separating the surface extension from the blade;
contacting the blade with another wafer; and
supplying the applied vacuum to the vacuum distribution manifold to grip the other wafer with the end effector.

D10. The method of any of paragraphs D1-D9, wherein the method includes performing the contacting, the attaching the surface extension, the positioning the end effector, and the supplying the pressurized gas stream while the blade is affixed to a wafer-handling robot.

D11. The method of any of paragraphs D1-D10, wherein the method includes performing the contacting, the attaching the surface extension, the positioning the end effector, and the supplying the pressurized gas stream to engage the wafer without first teaching a/the wafer-handling robot.

D12. The method of any of paragraphs D1-D11, wherein the wafer-handling end effector includes any suitable structure, function, and/or feature of any of the wafer-handling end effectors of any of paragraphs A1-A81, any of the wafer-handling units of any of paragraphs B1-B11, and/or any of the systems of any of paragraphs C1-C6.

D13. A system configured to perform a process operation on a wafer, the system comprising:
a wafer-handling unit that includes a wafer-handling end effector; and
a controller programmed to control the operation of the wafer-handling unit according to any suitable step, function, and/or feature of any of the methods of any of paragraphs D1-D12.

D14. The system of paragraph D13, wherein the system further includes any suitable structure, function, and/or feature of any of the wafer-handling end effectors of any of paragraphs A1-A81, any of the wafer-handling units of any of paragraphs B1-B11, and/or any of the systems of any of paragraphs C1-C6.

### INDUSTRIAL APPLICABILITY

The systems, wafer-handling units, wafer-handling end effectors, and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A wafer-handling end effector configured to selectively engage a wafer via a pressure force and to selectively grip the wafer via a vacuum force, the end effector comprising:
a blade that defines a blade vacuum force retention side and an opposed blade pressure force retention side;
a gas distribution manifold that extends at least partially within the blade and is in fluid communication with the blade pressure force retention side; and
a vacuum distribution manifold that extends at least partially within the blade, is fluidically isolated from the gas distribution manifold within the blade, and is in fluid communication with the blade vacuum force retention side.

2. The end effector of claim 1, wherein the blade vacuum force retention side is an upper side of the blade and the blade pressure force retention side is a lower side of the blade.

3. The end effector of claim 1, wherein the end effector further includes a surface extension, wherein the surface extension defines:
(i) an extension pressure force retention side that extends away from the blade and at least partially around the blade pressure force retention side, and
(ii) an extension attachment region that extends across the blade vacuum force retention side of the blade and is configured to permit selective attachment of the surface extension to the blade and selective separation of the surface extension from the blade.

4. The end effector of claim 3, wherein the selective attachment is via at least one of application of the vacuum force and activation of an attachment mechanism, and further wherein the selective separation is via at least one of cessation of the vacuum force and deactivation of the attachment mechanism.

5. The end effector of claim 3, wherein the surface extension defines an average extension thickness, as measured in a direction that is perpendicular to the extension pressure force retention side, and further wherein a ratio of the extension thickness to a blade thickness of the blade is at least 1.

6. The end effector of claim 3, wherein the extension attachment region defines a blade-receiving region, and further wherein the blade extends within the blade-receiving region.

7. The end effector of claim 6, wherein the blade-receiving region includes a blade-receiving recess defined within the surface extension, and further wherein the extension pressure force retention side extends away from the blade-receiving recess.

8. The end effector of claim 6, wherein the blade-receiving region defines a vacuum-receiving surface configured to at least one of:
(i) receive an applied vacuum from the blade vacuum force retention side of the blade;
(ii) contact the blade vacuum force retention side of the blade; and
(iii) define a face-to-face contact with the blade vacuum force retention side of the blade.

9. The end effector of claim 6, wherein the blade pressure force retention side projects from the extension pressure force retention side.

10. The end effector of claim 6, wherein the blade-receiving region is shaped to at least partially receive a blade-wafer overlap region of the blade.

11. The end effector of claim 3, wherein the surface extension includes at least three projecting regions that project from the extension pressure force retention side, wherein the at least three projecting regions are configured to physically contact the upper surface of the wafer when the end effector selectively engages the wafer.

12. The end effector of claim 11, wherein, when the end effector selectively engages the wafer, the at least three projecting regions are configured to resist sliding motion relative to the wafer via a static friction force between the wafer and a projection end of each of the at least three projecting regions.

13. The end effector of claim 3, wherein the surface extension is a first surface extension, wherein the end effector includes a second surface extension, and further wherein the end effector is configured to permit selective attachment and selective separation of one of the first surface extension and the second surface extension to the blade at a given time.

14. The end effector of claim 13, wherein the first surface extension defines a first surface extension shape, and further wherein the second surface extension defines a second surface extension shape that differs from the first surface extension shape.

15. A wafer-handling unit, comprising:
a wafer-handling robot; and
the end effector of claim 1, wherein the end effector is operatively attached to the wafer-handling robot via a blade mounting structure of the blade.

16. The wafer-handling unit of claim 15, wherein the wafer-handling unit further includes:
(i) a vacuum source configured to selectively supply an applied vacuum to the vacuum distribution manifold to generate the vacuum force; and
(ii) a pressurized gas source configured to selectively supply a pressurized gas stream to the gas distribution manifold to generate the pressure force.

17. A system configured to perform an operation on a wafer, the system comprising:
a chuck that defines a support surface configured to support the wafer; and
the wafer-handling unit of claim 15, wherein the wafer-handling unit is configured to selectively position the wafer on the support surface and to selectively remove the wafer from the support surface.

18. A method of utilizing a wafer-handling end effector configured to engage a wafer via a pressure force, the method comprising:
contacting a blade of the end effector with a surface extension of the end effector;
attaching the surface extension to the blade;
positioning the end effector proximate a surface of the wafer; and
supplying a pressurized gas stream to a gas distribution manifold of the blade to engage the wafer via the pressure force.

19. The method of claim 18, wherein the surface extension is a first surface extension, wherein the wafer is a first wafer, and further wherein, subsequent to the supplying the pressurized gas stream for at least a threshold wafer transfer time, the method further includes:
ceasing supply of the pressurized gas stream;
ceasing attachment of the surface extension to the blade;
separating the first surface extension from the blade; and
sequentially repeating the contacting, the attaching the surface extension, the positioning, and the supplying the pressurized gas stream utilizing a second surface extension, which differs from the first surface extension, to engage a second wafer of at least one of a second wafer diameter, a second wafer shape, and a second wafer size, that differs from at least one of a first wafer diameter, a first wafer shape, and a first wafer size of the first wafer.

20. The method of claim 18, wherein subsequent to the supplying the pressurized gas stream for at least a threshold wafer transfer time, the method further includes:
ceasing the attachment of the surface extension;
separating the surface extension from the blade;
contacting the blade with another wafer, and
supplying the applied vacuum to the vacuum distribution manifold to grip the other wafer with the end effector.
